(19) United States
(12) Patent Application Publication
(10) Pub. No.: US 2009/0115292 A1
(43) Pub. Date: May 7, 2009

(54) STRAIN AMPLIFICATION DEVICES AND METHODS

(75) Inventors: Jun Ueda, Duluth, GA (US); Haruhiko Harry Asada, Lincoln, MA (US); Thomas William Secord, Cambridge, MA (US)

Correspondence Address: MILLS & ONELLO LLP, ELEVEN BEACON STREET, SUITE 605, BOSTON, MA, 02108, US

(73) Assignee: MASSACHUSETTS INSTITUTE OF TECHNOLOGY, Cambridge, MA (US)

(21) Appl. No.: 12/257,850

(22) Filed: Oct. 24, 2008

Related U.S. Application Data
(60) Provisional application No. 61/000,365, filed on Oct. 25, 2007.

(51) Int. Cl. H01L 41/113

(52) U.S. Cl. 310/338

(57) ABSTRACT

A multi-layer strain-amplification device includes at least one first amplifying layer unit and a second amplifying layer unit positioned about the at least one first amplifying layer unit. A strain of the at least one first amplifying layer unit is amplified by the second amplifying layer unit.

### RELATED APPLICATIONS

This application claims the benefit of U.S. Provisional Patent Application No. 61/000,365, filed Oct. 25, 2007, the content of which is incorporated herein by reference in its entirety.

### FIELD OF THE INVENTION

The invention relates to strain amplification devices and methods, specifically to multi-layer strain amplification devices and methods having hierarchical nested structures and comprising piezoelectric materials.

### BACKGROUND OF THE INVENTION

The demand for high-force and compact actuators with large strain is increasing in robotics. Piezoelectric (PZT) ceramic material, such as lead zirconium titanate, is known as one of the promising materials used in actuators because of its high power density, high bandwidth, and high efficiency.

FIG. 1 is a chart illustrating a comparison of characteristics between PZT and other materials used to form actuators. As shown in FIG. 1, PZT outperforms other actuator materials, such as shape memory alloy (SMA), conducting polymers, such as polypyrrole-conducting polymers, and electrostrictive polymers, also referred to as elastomers, with respect to speed of response, large stress, and bandwidth. The maximum stress of PZT is comparable to that of SMA, and the efficiency of PZT is comparable to that of elastomers. Furthermore, PZT is a stable and reliable material that can be used in diverse, harsh environments. Polypyrrole-conducting polymers, on the other hand, degrade quickly despite their attractive features such as relatively high stress.

However, PZT has two drawbacks. A first drawback of PZT is its extremely small strain, as shown in section A of FIG. 1. A second drawback of PZT is hysteresis. However, hysteresis can be overcome by binary segmented control. See B. Selden, K. J. Cho, and H. Asada, “Segmented Binary Control of Shape Memory Alloy Actuator Systems Using the Peltier Effect,” Proceedings of 2004 IEEE International Conference on Robotics and Automation (ICRA) '04, vol. 5, Apr. 26-May 1, 2004, pp. 4931-4936, incorporated herein in its entirety by reference.

The inherently small strain of PZT, i.e., approximately 0.1%, can be a major issue for broad applications. Over the last several decades, several approaches have been taken to increase PZT strain, and generate displacements from PZT that are large enough to drive systems used in robotics and mechatronics, described for example, in C. Niezrecki, D. Brei, S. Balakrishnan, and A. Moskalik, A., entitled “Piezoelectric Actuation: State of the art,” The Shock and Vibration Digest, 33(4), pp. 269-280, 2001, R. Newnham, A. Dogan, Q. Xu, K. Onitsuka, J. Tressler, and S. Yoshikawa, “Flextensional Moonie Actuators,” 1993 IEEE Proceedings, Ultrasonics Symposium, vol. 1, Oct. 31-Nov. 3, 1993, pp. 509-513, U.S. Pat. No. 6,574,958 entitled “Shape Memory Alloy Actuators and Control Methods,” issued Jun. 10, 2003, A. Dogan, Q. Xu, K. Onitsuka, S. Yoshikawa, K. Uchino, and R. Newnham, “High Displacement Ceramic Metal Composite Actuators (Moonies),” Ferroelectrics, 156(1), pp. 1-6, 1994, G. Haertling, “Rainbow Ceramics—A New Type of Ultra-High Displacement Actuator,” American Ceramic Society Bulletin, 73(1), pp. 93-94, 1994, K. Onitsuka, A. Dogan, J. Tressler, Q. Xu, S. Yoshikawa, and R. Newnham, “Metal-Ceramic Composite Transducer, the ‘Moonie’,” Journal of Intelligent Material Systems and Structures 6(4), pp. 447-455, 1995, A. Moskalik and D. Brei, “Quasi-Static Behavior of Individual C-Block Piezoelectric Actuators,” Journal of Intelligent Material Systems and Structures, 8(7), pp. 571-587, 1997, K. Uchino, Piezoelectric Actuators and Ultrasonic Motors, Kluwer Academic Publishers, 1997, A. Dogan, K. Uchino, and R. Newnham, “Composite Piezoelectric Transducer with Truncated Conical Endcaps ‘cymbal’,” Ultrasonics, Ferroelectrics and Frequency Control, IEEE Transactions on, 44(3), pp. 597-605, May, 1997, U.S. Pat. No. 4,435,666 entitled “Lever Actuator Comprising a Longitudinal-Effect Electroexpansive Transducer,” issued Mar. 6, 1994, P. Janker, M. Christmann, F. Hermle, T. Lorkowski, and S. Storm, “Mechatronics Using Piezoelectric Actuators,” Journal of the European Ceramics Society, 19(6), pp. 1127-1131, 1999, C. Niezrecki, D. Brei, D. Balakrishnan, and A. Moskalik, “Piezoelectric Actuation: State of the Art,” the Shock and Vibration Digest, 33(4), pp. 269-280, 2001, K. Seffen and E. Toews, “Hyperthetical Actuators: Coils and Coiled-Coils,” 45th AiAA/ASME/ASCE/AHS/ASC Structures, Structural Dynamics and Materials Conference, pp. 19-22, 2004, and N. Conway, Z. Traina, and S. Kim, “A Strain Amplifying Piezoelectric MEMS Actuator,” Journal of Micromechanics and Microengineering, 17(4), pp. 781-787, 2007, each incorporated herein in its entirety by reference.

Such approaches include a) inching motion or periodic wave generation, b) bimetal-type bending, c) leverage-type motion amplification, and d) flextensional mechanisms. However, inching motion entails friction drive, which limits its applicability to a class of applications. Bimetal-type mechanisms, for example, described in K. Seffen and E. Toews, “Hyperthetical Actuators: Coils and Coiled-Coils,” incorporated by reference above, can produce only small forces despite their large displacement and strain, which also limit applications to small loads. See Germano, Carmen P., entitled “Flexure Mode Piezoelectric Transducers”, IEEE Transactions on Audio and Electroacoustics, vol. AU-19, No. 1, Mar. 1971, incorporated herein in its entirety by reference. Leverage-type motion amplification, for example, described in U.S. Pat. No. 4,435,666 incorporated by reference above, is inefficient, producing only a marginal gain on the order of 10. Systems incorporating leverage-type motion amplification tend to be bulky and heavy if several leverages are connected together to produced a larger displacement.

A wide variety of flextensional mechanisms has been studied and developed. U.S. Pat. No. 4,999,819, issued Mar. 12, 1991, entitled “Transformed Stress Direction Acoustic Transducer,” incorporated herein in its entirety by reference, provides a method for amplifying strain of an enclosed piezoelectric actuator sandwiched between two flexible, curved elements. The mechanism that applies this method is called a “Moonie” and has been widely used for strain amplification. See U.S. Pat. No. 6,411,009, entitled “Piezoelectric Actuator System,” issued Jun. 25, 2002, incorporated herein in its entirety by reference. See also R. Newnham, A. Dogan, Q. Xu, K. Onitsuka, J. Tressler, and S. Yoshikawa, “Flextensional Moonie Actuators,” 1993 IEEE Proceedings, Ultrasonics Symposium, vol. 1, Oct. 31-Nov. 3, 1993, pp. 509-513, A. Dogan, Q. Xu, K. Onitsuka, S. Yoshikawa, K. Uchino, and R. Newnham, “High Displacement Ceramic Metal Composite Actuators (Moonies),” Ferroelectrics, 156(1), pp. 1-6, 1994, and K. Onitsuka, A. Dogan, J. Tressler, Q. Xu, S. Yoshikawa, and R. Newnham, “Metal-Ceramic Composite Transducer, the ‘Moonie’,” Journal of Intelligent Material Systems and Structures 6(4), pp. 447-455, 1995 each incorporated by reference above. Other flextensional mechanisms include “Cymbol,” for example, described in A. Dogan, K. Uchino, and R. Newnham, “Composite Piezoelectric Transducer with Truncated Conical Endcaps ‘cymbal’,” Ultrasonics, Ferroelectrics and Frequency Control, IEEE Transactions on, 44(3), pp. 597-605, May, 1997, incorporated by reference above, “Rainbow,” for example, described in G. Haertling “Rainbow Ceramics—A New Type of Ultra-High Displacement Actuator,” American Ceramic Society Bulletin, 73(1), pp. 93-94, 1994, and other conventional flextensional mechanisms, for example, described in P. Janker, M. Christmann, F. Hermle, T. Lorkowski, and S. Storm, “Mechatronics Using Piezoelectric Actuators,” Journal of the European Ceramics Society, 19(6), pp. 1127-1131, 1999, each incorporated by reference above.

Although the “Moonie” strain amplification methods described above, in particular, with regard to U.S. Pat. No. 4,999,819 and U.S. Pat. No. 6,411,009, are known to be relatively efficient methods, the resulting expected amplification gain produced by the Moonie is less than 20, resulting in less than a 2% effective strain.

Other methods, described in U.S. Pat. No. 5,471,721, entitled “Method for Making Monolithic Prestressed Ceramic Devices,” issued Dec. 5, 1995, incorporated herein in its entirety by reference, disclose making monolithic pre-stressed piezoelectric ceramics, referred to as a “rainbow actuator,” having a stress amplification mechanism. U.S. Pat. No. 6,574,958, entitled “Shape Memory Alloy Actuators and Control Methods,” issued Jun. 10, 2003, incorporated herein in its entirety by reference, provides stroke-multiplying shape memory alloy actuators by stacking several layers in a compact body. However, these methods likewise tend to be bulky and heavy, since the amplification gain produced by the actuators is only proportional to the dimension of the stacked layers.

Systematic design methods have also been studied, for example, S. Canfield and M. Frecker, “Topology Optimization of Compliant Mechanical Amplifiers for Piezoelectric Actuators,” Structural and Multidisciplinary Optimization, 20(4), pp. 269-279, 2000, E. Silva, S. Nishiwaki, and N. Kikuchi, “Topology Optimization Design of Flextensional Actuators,” Ultrasonics, Ferroelectrics, and Frequency Control,” IEEE Transactions on, 47(3), pp. 657-671, 2000, and G. Nader, E. Silva, and J. Adamowski, “Characterization of Novel Flextensional Transducers Designed by Using Topology Optimization Method,” Ultrasonics Symposium, 2001 IEEE, 2, pp. 981-984, 2001, each incorporated herein in its entirety by reference. An individual actuator, such as C-block, for example, described in A. Moskalik and D. Brei, “Quasi-Static Behavior of Individual C-Block Piezoelectric Actuators,” Journal of Intelligent Material Systems and Structures, 8(7), pp. 571-587, 1997 and Moonie, for example, described in K. Onitsuka, A. Dogan, J. Tressler, Q. Xu, S. Yoshikawa and R. Newnham, “Metal-Ceramic Composite Transducer, the ‘Moonie’,” Journal of Intelligent Material Systems and Structures 6(4), pp. 447-455, 1995, each incorporated by reference above, can be stacked in series to increase the total displacement. However, this stacking also increases the size of the overall mechanism and does not improve the strain itself, which is limited to 2-3%, e.g., by conventional flextensional mechanisms.

Therefore, there is a need for a compact actuator with larger strain that is necessary for driving a wide variety of mechatronic systems.

### SUMMARY OF INVENTION

Accordingly, a feature of the present invention is to provide devices and methods that comprise a hierarchical cellular structure for providing strain amplification, thereby achieving strain that is significantly greater than conventional strain amplification devices and methods. Another feature of the present invention is to build a modular structure that is flexible and extensible.

In accordance with an aspect of the invention, a multi-layer strain amplification device comprises at least one first amplifying layer unit including a plurality of actuators; and a second amplifying layer unit positioned about the at least one first amplifying layer unit, wherein a strain of the at least one first amplifying layer unit is amplified by the second amplifying layer unit.

In an embodiment, the at least one first amplifying layer unit and the second amplifying layer unit are configured as a nested rhombus structure.

In an embodiment, the actuators are in series with and/or parallel with each other.

In an embodiment, an output axis of the serially-connected actuators is perpendicular to an output axis of the second amplifying layer unit.

In an embodiment, the actuators are piezoelectric actuators.

In an embodiment, the at least one first amplifying unit is positioned in a first layer of the device, the at least one second amplifying unit strain is positioned in a second layer of the device, wherein an amplification gain of the device increases exponentially as a number of layers of the device increases.

In an embodiment, the device further comprises a third amplifying layer unit positioned about at least one second amplifying layer unit.

In an embodiment, the at least one first amplifying layer unit, the at least one second amplifying layer unit, and the third amplifying unit are configured as a nested rhombus structure.

In an embodiment, the at least one first amplifying unit is positioned in a first layer of the device, the at least one second amplifying unit strain is positioned in a second layer of the device, and the third amplifying layer is positioned in a third layer of the device, wherein an amplification gain of the device increases exponentially as a number of layers of the device increases.

In an embodiment, displacements of each first actuator are aggregated and transmitted through the at least one first amplifying layer unit and the second amplifying layer unit, resulting in an output displacement at the second amplifying layer unit.

In an embodiment, a displacement of the device is amplified when the at least one first amplifying unit expands in a first direction and contracts in a second direction.

In an embodiment, the first direction is perpendicular to the second direction.

In an embodiment, the at least one first amplifying layer unit further comprises a rhombus structure positioned about each actuator, the rhombus structure including a rigid beam and a flexible joint.

In an embodiment, a plurality of first amplifying layer units are connected in series to increase an output displacement.

In an embodiment, a plurality of first amplifying layer units are connected in parallel to increase an output force.

In accordance with another aspect of the invention, a method of forming a multi-layer strain amplification device comprises providing at least one first amplifying layer unit including a plurality of actuators; and positioning a second amplifying layer unit about the at least one first amplifying layer unit to amplify a strain of the at least one first amplifying layer unit.

In an embodiment, the at least one first amplifying layer unit and the second amplifying layer unit are configured as a nested rhombus structure.

In an embodiment, the actuators are positioned to be in series with and/or parallel with each other.

In an embodiment, the at least one first amplifying unit is positioned in a first layer of the device, the at least one second amplifying unit strain is positioned in a second layer of the device, wherein an amplification gain of the device increases exponentially as a number of layers of the device increases.

In an embodiment, a third amplifying layer unit is positioned about at least one second amplifying layer unit.

In an embodiment, the at least one first amplifying layer unit, the at least one second amplifying layer unit, and the third amplifying unit are configured as a nested rhombus structure.

In an embodiment, the at least one first amplifying unit is positioned in a first layer of the device, the at least one second amplifying unit strain is positioned in a second layer of the device, and the third amplifying layer is positioned in a third layer of the device, wherein an amplification gain of the device increases exponentially as a number of layers of the device increases.

In an embodiment, a displacement of the device is amplified when the at least one first amplifying unit expands in a first direction and contracts in a second direction.

In an embodiment, a rhombus structure is positioned about each actuator, the rhombus structure including a rigid beam and a flexible joint.

In accordance with another aspect, a method of amplifying strain of an actuator comprises providing at least one first amplifying layer unit having a first strain; amplifying the first strain; positioning a second amplifying layer unit about the at least one first amplifying layer unit; and amplifying the amplified first strain.

### BRIEF DESCRIPTION OF THE DRAWINGS

The present invention will become more apparent in view of the attached drawings and accompanying detailed description. The embodiments depicted herein are provided by way of example, not by way of limitation, wherein like reference numerals refer to the same or similar elements throughout the different views. The drawings are not necessarily to scale, emphasis instead being placed upon illustrating aspects of the invention. In the drawings:

FIG. 1 is a chart illustrating a comparison of characteristics between PZT and other actuator materials;

FIGS. 2A and 2B are perspective views of a strain amplification mechanism having first and second positions, respectively, according to embodiments of the invention;

FIG. 3 is a schematic illustration of a strain amplification mechanism, according to embodiments of the invention;

FIG. 4 is a schematic view of the strain amplification mechanism of FIG. 3 illustrating strain amplification, according to embodiments of the invention;

FIG. 5 is a two-dimensional schematic view of a multi-layer strain amplification device, according to embodiments of the invention;

FIG. 6 is a three-dimensional schematic view of a multi-layer strain amplification device, according to embodiments of the invention;

FIG. 7 is a diagram illustrating an actuator coordinate system of a PZT stack actuator, according to embodiments of the invention;

FIG. 8A is a graph illustrating an amplified strain produced by the multi-layer strain amplification mechanism of FIG. 6, according to embodiments of the invention;

FIG. 8B is a graph illustrating a reduced blocking force of the multi-layer strain amplification mechanism of FIG. 6, according to embodiments of the invention;

FIG. 9 is a three-dimensional view of a three-layer strain amplification device, according to embodiments of the invention;

FIG. 10 is a view of a model of an actuator unit connected to a spring load, according to embodiments of the invention;

FIGS. 11A and 11B are views of a rhombus illustrating the effects of joint stiffness on free-load displacement, according to embodiments of the invention;

FIGS. 12A and 12B are views of a rhombus illustrating the effects of beam compliance on a blocking force, according to embodiments of the invention;

FIG. 13 is a view of a structural model of a Moonie, according to embodiments of the invention;

FIG. 14A is a view of a rhombus mechanism having structural flexibilities, according to embodiments of the invention;

FIG. 14B is a view of a lumped parameter model, according to embodiments of the invention;

FIG. 14C is a view of a model of a rhombus mechanism with flexibility, according to embodiments of the invention;

FIG. 15 is a simplified representation of a lumped parameter model, according to embodiments of the invention;

FIG. 16 is an illustration of a nested rhombus model, according to embodiments of the invention;

FIG. 17 is a graph illustrating a force-displacement relationship for the nested rhombus structure shown in FIG. 16, according to embodiments of the invention;

FIG. 18 is an illustration of a compliant joint for an amplifying layer unit, according to embodiments of the invention.

FIG. 19 is a view of an actuator for a first amplifying layer unit, according to embodiments of the invention;

FIG. 20 is a view of a second layer rhombus structure, according to embodiments of the invention;

FIG. 21 is a graph illustrating a calculated force and displacement property of the second layer rhombus structure of FIG. 20, according to embodiments of the invention;

FIG. 22A is a different view of the second layer rhombus structure of FIG. 19, according to embodiments of the invention;

FIG. 22B is an illustration of an amplification device having two amplification layers;

FIGS. 22C and 22D are views of the amplification device of FIG. 22B in OFF and ON positions, according to embodiments of the invention;

FIG. 23 is a view of two amplification devices connected in series, and in OFF and ON positions, respectively, according to embodiments of the invention;

FIGS. 24A and 24B are graphs illustrating experimental results, including free-load displacement: step response, and blocking-force, respectively, based on sinusoidal wave input, according to embodiments of the invention;

FIG. 25 is a graph showing aggregate displacements when ON-OFF controls are provided to internal units, according to embodiments of the invention;

FIG. 26A is an illustration of a cellular actuator comprising six units connected in series, according to embodiments of the invention;

FIG. 26B is an illustration of a cellular actuator comprising six stacks connected in series and four bundles connected in parallel, according to embodiments of the invention;

FIG. 26C is an illustration of a cellular actuator comprising six stacks connected in series and seven bundles connected in parallel, according to embodiments of the invention;

FIG. 27 is an illustration of the cellular actuator of FIG. 26B reconfigured by changing connectors.

FIG. 28 is a perspective view of a cell stack and bundle, according to embodiments of the invention;

FIG. 29 is a perspective view of an actuator incorporating the cell stack and bundle shown in FIG. 28, according to embodiments of the invention;

FIGS. 30A and 30B are views of test equipment designed to measure free displacement and blocked force of designs, according to embodiments of the invention;

FIGS. 31A-31C are views of amplification mechanisms having different structures, according to embodiments of the invention;

FIGS. 32A and 32B are views of an amplification mechanism illustrating a blocked case and a free-load case, respectively, according to embodiments of the invention;

FIG. 33 is an illustration of characteristics of an amplification mechanism that is connected to a spring load by a fixed beam, according to embodiments of the invention;

FIG. 34 is an illustration of a parameter estimation of a three-spring model showing parameter estimation, according to embodiments of the invention;

FIGS. 35A and 35B are views of amplification mechanisms that are constrained, according to embodiments of the invention;

FIG. 36 is a view of lumped parameter model and simplified equivalent model, according to embodiments of the invention;

FIG. 37 is a view of lumped parameter model and simplified equivalent model showing a plurality of amplification mechanisms coupled to each other, according to embodiments of the invention; and

FIGS. 38A and 38B are graph illustrating ranges of gains for positive spring constants, according to embodiments of the invention.

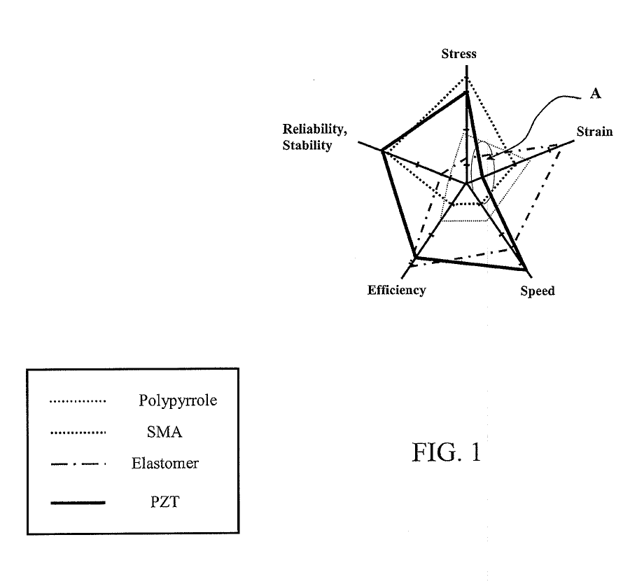

### DETAILED DESCRIPTION OF EMBODIMENTS

Hereinafter, aspects of the present invention will be described by describing illustrative embodiments in accordance therewith, with reference to the attached drawings. While describing these embodiments, detailed descriptions of well-known items, functions, or configurations are typically omitted for conciseness.

It will be understood that, although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

To address the abovementioned limitations of the prior art, in embodiments, systems and methods are provided that increase strain amplification by exponentially amplifying displacement of a PZT stack, which is particularly useful in applications related to robotics, for example, for increasing gain in a large strain in a compact body, wherein the gain is on the order of several hundreds, in an order of magnitude greater than a gain provided by conventional strain amplification mechanisms. For example, an original strain of a PZT stack is approximately 0.1%. However, the resultant nominal strain of the multi-layer strain amplification device in accordance with embodiments of the present invention can be at least 20%, which is comparable to that of natural skeletal muscles. Thus, the large strain PZT stack actuator in accordance with embodiments of the present invention can be used in a manner similar to biological muscles that are directly attached to skeletal structures. In other embodiments, the resultant nominal strain of the multi-layer strain amplification device in accordance with embodiments of the present invention can be at least 30%.

In order to drive a large load, however, care must be taken in the design of the strain amplification structure. In an embodiment, kinematic and static analysis can be performed to address how the output force and displacement are attenuated by joint stiffness and beam compliance with regard to the strain amplification device. In an embodiment, a lumped parameter model quantifies the performance degradation and facilitates design trade-offs.

In an embodiment, devices that produce this large strain amplification are based on a hierarchical nested structure. Such devices comprise two or more layers, wherein strain is amplified a times at each layer. This structure is fundamentally different from traditional layered structures, such as telescoping cylindrical units, for example, as disclosed in Niezrecki, C., Brei, D., Balakrishnan, S., and Moskalik, A., 2001. entitled “Piezoelectric Actuation: State of the art,” The Shock and Vibration Digest, 33(4), pp. 269-280, 2001, incorporated by reference above. This structure is also different from conventional approaches, which include stacking multiple plates that are connected by actuator wires, as disclosed for example in U.S. Pat. No. 6,574,958, incorporated by reference above.

Unlike these conventional leverage mechanisms, where the gain α is proportional to the dimensions of the layer or number of stacks, the amplification gain of the multi-layer strain amplification device based on the hierarchical nested structure described in the embodiments herein increases exponentially as the number of layers in the device increases. In an embodiment, for K layers of the hierarchical nested structure, the resultant gain is given by α^{K}, the power of the number of layers. Accordingly, this hierarchical nested structure includes a nested rhombus structure, wherein an actuator stack comprising piezoelectric material, for example, PZT, is formed inside of a rhombus structure such as a Moonie actuator, which is then nested inside another rhombus structure, allowing a gain a large strain in a compact body to be achieved, preferably having an effective strain of 20-30%, or greater.

The basic module of the hierarchical nested structure is an actuator unit, referred to herein as an internal unit, which, in an embodiment, is based on a Moonie mechanism, for example, R. Newnham, A. Dogan, Q. Xu, K. Onitsuka, J. Tressler, and S. Yoshikawa, “Flextensional Moonie Actuators,” 1993 IEEE Proceedings, Ultrasonics Symposium, vol. 1, Oct. 31-Nov. 3, 1993, pp. 509-513, incorporated by reference above. In an embodiment, the actuator unit is a piezoelectric actuator or a compact modular PZT stack actuator. In other embodiments, a plurality of modular actuator units can be connected to each other in series to increase the output displacement, or connected to each other in parallel to increase the output force, or connected as a combination of both serial and parallel to increase both displacement and output force. In this manner, an hierarchical structure can be formed, wherein one or more actuator units are enclosed within a larger amplifying layer unit structure, referred to herein as an amplification mechanism or amplifying mechanism, resulting in the amplifying layer unit having desirable diverse stroke, force, and impedance characteristics. In embodiments, these characteristics can be adjusted so that the amplifying layer unit has predetermined stroke, force, and impedance characteristics by changing the parallel and serial combinations of the actuator units. Further, in other embodiments, a plurality of first amplifying layer units can be combined together in a hierarchical structure in serial, in parallel, or a combination of both, to form a second amplifying layer unit, resulting in greater amplification of the total displacement and/or output force. Thus, an amplifying layer unit constructed from many actuator modules according to embodiments similar to those described herein can permit new control and drive systems to implement the amplifying layer units.

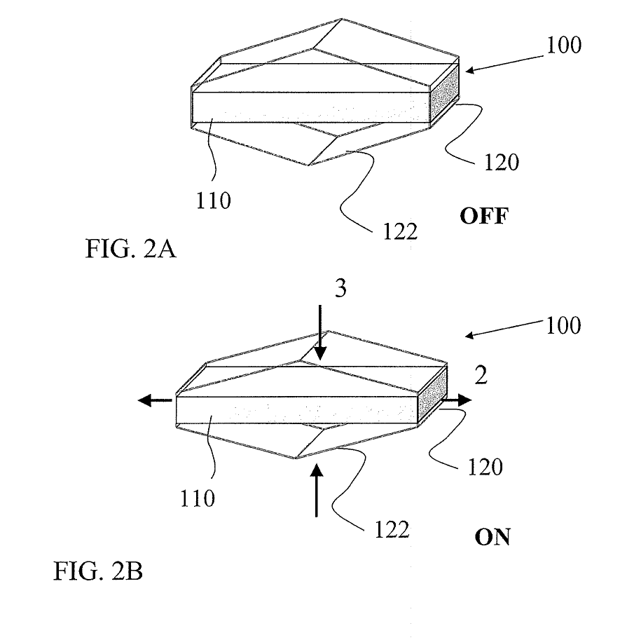

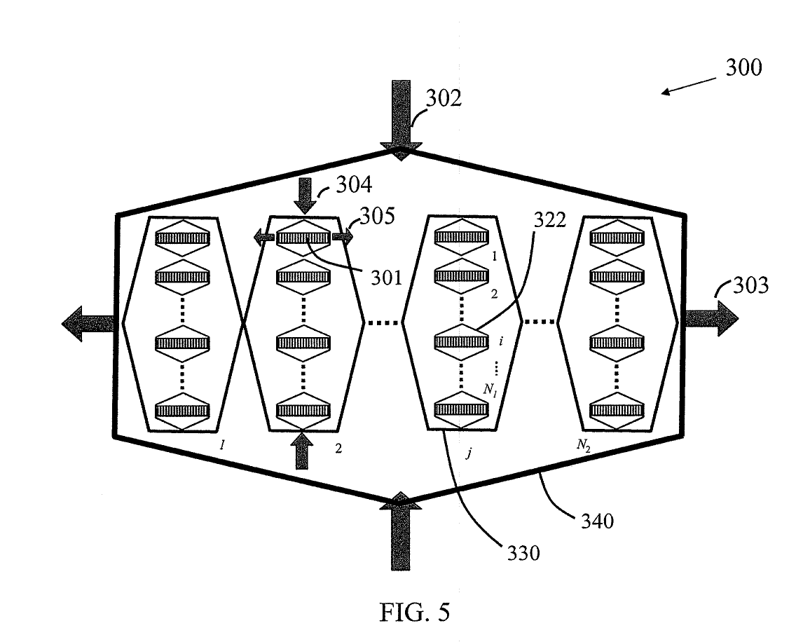

As described above, an output force and displacement of an amplifying layer unit are the aggregate effects of a plurality of modular actuator units combined together in an hierarchical nested structure, illustrated for example in FIGS. 5, 6, and 9. Simple ON-OFF controls can suffice to drive individual actuator units, illustrated for example in FIGS. 2A, 2B, since the aggregate outputs will be smooth and approximately continuous if a large number of modules are involved. See Ueda, J., Odhner, L., and Asada, H., “A Broadcast-Probability Approach to the Control of Vast DOF Cellular Actuators,” Proceedings of 2006 IEEE International Conference on Robotics and Automation (ICRA '06), May 15-19, 2006, pp. 1456-1461 and Ueda, J., Odhner, L., and Asada, H., “Broadcast Feedback of Stochastic Cellular Actuators Inspired by Biological Muscle Control,” The International Journal of Robotics Research,” 26(11-12), pp. 1251-1265, 2007, each incorporated herein in its entirety by reference. Accordingly, expensive analog drive amplifiers are not required. Moreover, ON-OFF controls are effective to overcome prominent hysteresis and nonlinearity of actuator materials, as addressed in J. Ueda, L. Odhner, S.-G. Kim, and H. Asada, “Distributed Stochastic Control of Mems-PZT Cellular Actuators with Broadcast Feedback,” The First IEEE/RAS-EMBS International Conference on Biomedical Robotics and Biomechatronics (BioRob 2006), Feb. 20-22, 2006, pp. 272-277 and J. Ueda, L. Odhner, and H. Asada, “A Broadcast-Probability Approach to the Control of Vast DOF Cellular Actuators,” Proceedings of 2006 IEEE International Conference on Robotics and Automation (ICRA '06), May 15-19, 2006, pp. 1456-1461, each incorporated herein in its entirety by reference. Thus, a modular actuator unit can be used as a building block for a cellular actuator inspired by biological muscles, in which a single actuator system is synthesized by connecting numerous small actuator units in serial, in parallel, or a mixture of both.

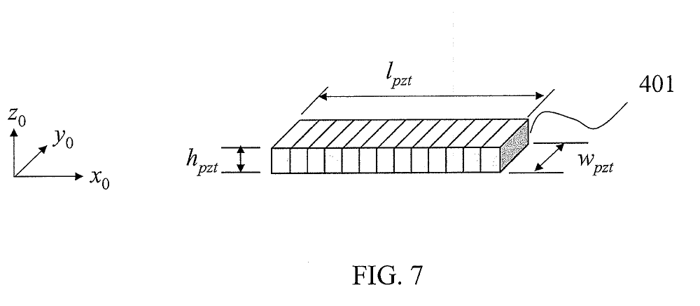

FIGS. 2A and 2B are perspective views of an amplification mechanism 100 in first and second positions, respectively, according to embodiments of the invention. In an embodiment, the amplification mechanism 100, referred to herein as a first amplifying layer unit, comprises an internal unit 110 and a rhombus structure 120. In an embodiment, the internal unit 110 comprises piezoelectric material known to those of ordinary skill in the art, such as PZT. In an embodiment, the internal unit 110 is a PZT stack actuator, for example, illustrated at least at FIG. 7. In an embodiment, the amplification mechanism 100 comprises a Moonie mechanism similar to that described herein.

As shown in FIG. 2A, the first position can be an OFF position. As shown in FIG. 2B, the second position can be an ON position. A local control unit (not shown) can control an internal unit 110 by applying binary controls in an ON-OFF manner, which can overcome the hysteresis of the material of the internal unit 110. As shown in FIG. 2B, the rhombus structure 120 is a rhombus-like hexagon that contracts vertically in the direction of 3 as the internal unit 110 expands in the direction of 2. As a result, the vertical displacement 3, that is, the output of the mechanism 100, is amplified if the angle of the oblique beams 122 relative to the horizontal axis is less than 45 degrees (θ).

In an embodiment, the amplification mechanism 100 is a first layer unit that is connected to other amplification mechanisms in serial, in parallel, or a mixture of both, which are positioned in a second rhombus structure to form a hierarchical nested structure.

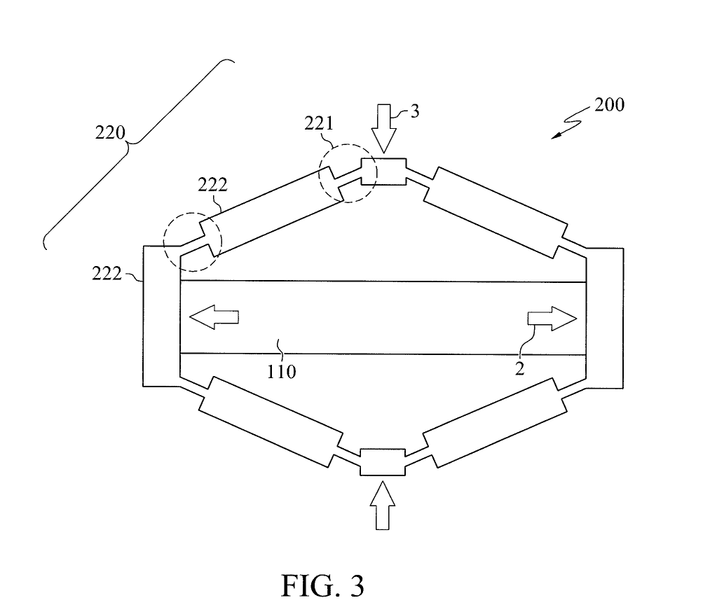

FIG. 3 is a schematic view of an amplification mechanism 200, according to embodiments of the invention. As shown in FIG. 3, the amplification mechanism 200, also referred to as a first amplifying layer unit or a rhombus mechanism, comprises a rhombus structure 220 comprising a plurality of rigid beams 222 that are connected together by flexible joints 221. The amplification mechanism 200 can be configured as a rhombus-like hexagon which is attached to an internal unit 110. A local control unit (not shown) can cause the internal unit 110 to expand or contract by applying binary controls in a manner similar to that described above with regard to FIG. 2B. The compliant joints 221 can therefore deform as the internal unit 110 deforms. As a result, an output 3 of the amplification mechanism 200 is amplified.

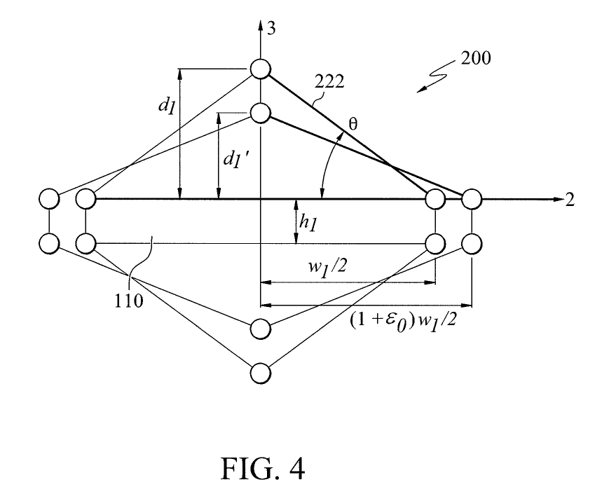

FIG. 4 is a schematic illustration of the amplification mechanism of FIG. 3 illustrating how strain is amplified, according to embodiments of the invention. In an embodiment, the internal unit 110 is extensible. The following formulation is readily applied to the structure with a contractive internal unit. Let h₁, w₁, and ε₀ be the height, width, and strain, respectively of the internal unit 110. Also let d₁ be the initial gap between the surface of the internal unit 110 and the apex of the amplification mechanism. Assume that all the joints (not shown) are purely or freely rotational revolving and all the beams 222 are completely rigid. Also assume that the internal unit 110 is extensible, and can be extended to a contractive case in accordance with the following formulation. In an embodiment, as the internal unit 110 expands, the gap d₁ contracts to d′₁, by the extension of the internal unit 110:

d′₁=\sqrt{d₁²−(ε₀²+2ε₀)w₁²/4}. (1)

Then, the amplification gain α₁ of the displacement is given by

$${a}_{1} = \frac{2 Δ {x}_{1}}{{ɛ}_{0} {w}_{1}} \qquad ( 2 )$$

where Δx₁ [symbol] d₁−d′₁. For small ε₀ this can be approximated to:

$${a}_{1} = \frac{{w}_{1}}{2 {d}_{1}} = cot θ \qquad ( 3 )$$

where θ is the angle of the oblique beam 222 relative to the horizontal axis. In an embodiment, the instantaneous amplification gain does not apply to large strain because of the nonlinearity in equation (1). A smaller value for the angle θ of the oblique beams 222 results in a large amplification gain. However, the angle θ needs to be carefully determined in order to avoid buckling of the beams 222. In an embodiment, this amplification gain alone can increase displacement to 3-5 times larger.

In an embodiment, the initial length of the amplification mechanism is 2d₁+h₁ along the output axis. Since the displacement created in this output direction is 2Δx₁, the effective strain (ε₁) along the output axis can be defined as:

$${ɛ}_{1} {=}^{△} \frac{2 \vert {Δx}_{1} \vert}{2 {d}_{1} + {h}_{1}} \qquad ( 4 )$$

Comparing this to the input strain ε₀ yields the strain amplification defined by:

$${α}_{1} {=}^{△} \frac{{ɛ}_{1}}{{ɛ}_{0}} = {a}_{1} \frac{{w}_{1}}{2 {d}_{1} + {h}_{1}} \qquad ( 5 )$$

where w₁/(2d₁+h₁) is the ratio of the width to the height of the rhombus structure, i.e. the aspect ratio of the mechanism. In an embodiment, both the displacement amplification and the aspect ratio of the mechanism contribute to the resultant strain amplification α₁. Although the aspect ratio is not a strain amplifier, since 1) the effective strain amplification is defined to be the ratio of output displacement to the natural body length in the same direction as the output, and since 2) the direction of input strain and that of the output displacement are perpendicular to each other, the effective gain can nevertheless be amplified by the aspect ratio. Thus, increasing the aspect ratio increases the strain amplification gain α₁. However, space constraints as well as buckling of the internal unit 110, which, in an embodiment can be a PZT stack actuator, must be considered in determining the aspect ratio.

Amplification mechanisms for amplifying small displacements of PZT actuators have been developed both in macro scale, for example, described in R. Newnham, A. Dogan, Q. Xu, K. Onitsuka, J. Tressler, and S. Yoshikawa, “Flextensional Moonie Actuators,” 1993 IEEE Proceedings, Ultrasonics Symposium, vol. 1, Oct. 31-Nov. 3, 1993, pp. 509-513, incorporated by reference above, and in micro scale, for described in N. Conway, Z. Traina, and S. Kim, “A Strain Amplifying Piezoelectric MEMS Actuator,” Journal of Micromechanics and Microengineering, 17(4), pp. 781-787, 2007, incorporated by reference above. In addition, conventional amplification mechanisms have been applied to commercial products, for example, described Cedrat, Inc., http://www.cedrat.com, last downloaded on Oct. 24, 2007, the contents of which are incorporated herein in its entirety by reference. However, embodiments of the present invention extend this technique to gain an order-of-magnitude larger strain amplification and to build a modular structure that is flexible and extensible.

FIG. 5 is a two-dimensional schematic view of a multi-layer strain amplification device 300 according to embodiments of the invention. The multi-layer strain amplification device 300 comprises a plurality of amplification mechanisms 322 (i.e., 322₁, 322₂ . . . 322_{N1}), also referred to as first amplifying layer units or rhombus mechanisms, which are arranged in an hierarchical structure. In an embodiment, the first amplifying layer units 322 can be similar to the amplification mechanism 200 described above with regard to FIGS. 3 and 4.

A feature of the multi-layer strain amplification device 300 is that, in an embodiment, two or more planes of rhombi in different layers may be arranged to be perpendicular to each other, as shown in FIG. 5, in order to construct three-dimensional structures with diverse configurations. Accordingly, this construction results in a gain of an order-of-magnitude larger strain amplification, as well as a modular structure that is flexible and extensible. Further, in an embodiment, a three-dimensional arrangement of nested rhombus structures permits many rhombus units to be densely enclosed in a limited space, to form a “nested rhombus” strain amplifier.

In an embodiment, each first amplifying layer unit 322 amplifies the strain of an enclosed internal unit 301. In an embodiment, the internal unit 301 comprises a PZT stack actuator. In an embodiment, the first amplifying layer units 322 are connected in series to increase an output displacement 304. In another embodiment, the first layer units 322 can be arranged in parallel to increase an output force. A salient feature of this hierarchical mechanism is that the first amplifying layer units 322 are enclosed within a larger structure to form a second amplifying layer unit 330 that further amplifies the total displacement 304 and/or output force (not shown) of the smaller first amplifying layer units 322. In an embodiment, the second amplifying layer unit 330 has a rhombus configuration. In an embodiment, a plurality of second amplifying layer units 330 (i.e., (i.e., 330₁, 322₂ . . . 322ⱼ, 322_{N2}), are connected together and enclosed with an even larger structure to form a third amplifying layer unit 340 to further amplify the total displacement 302. In an embodiment, the third amplifying layer unit 340 has a rhombus configuration. As this enclosure and amplification process is repeated, a multi-layer strain-amplification mechanism is constructed, and the resultant displacement 302 increases exponentially. Thus, the embodiment illustrated in FIG. 5 provides an example in which a plurality of first amplifying layer units 322 are connected in series and/or in parallel and enclosed by the second amplifying layer unit 330, and a plurality of second amplifying layer units 330 are connected in series and/or in parallel and enclosed by the third amplifying layer unit 340.

As described above, a unique feature of this hierarchical structure described herein is that a plurality of amplifying layer units or rhombus units can be enclosed within a larger amplifying layer unit or rhombus unit to amplify the total displacement of the smaller rhombus units. A plurality of these larger amplifying layer units or rhombus units in turn can be connected together and enclosed with an even larger amplifying layer unit or rhombus unit to further amplify the total displacement. Thus, since this enclosure and amplification procedure is repeated K times, the resultant displacement amplification increases exponentially.

This hierarchical nested structure can have a number of variations, depending on the number of the hierarchical layers and the numbers of serial and parallel units arranged in each layer. For example, let K be the number of layers of amplifying layer units, and assume that each amplifying layer unit amplified strain α times. The resultant amplification gain is given by α to the power of K:

αₜₒₜₐₗ=α^{K}. (6)

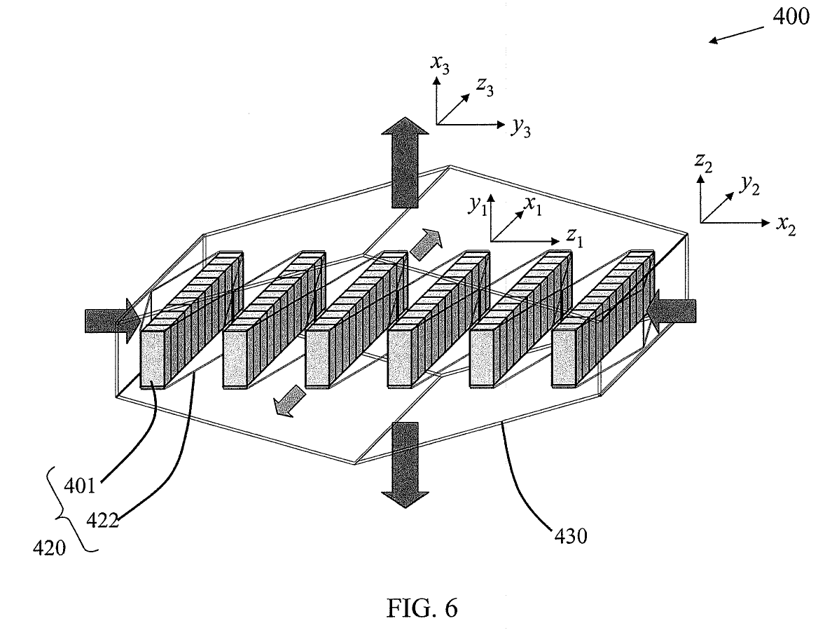

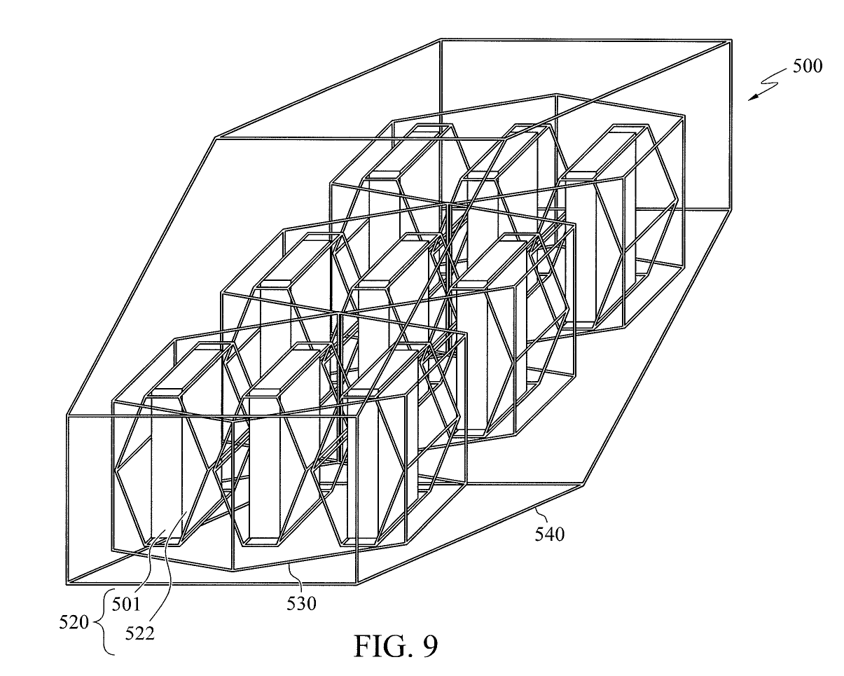

For α=15 the gain is αₜₒₜₐₗ=225 by nesting two layers of amplifying layer units, for example, as shown in FIG. 6, and the gain is αₜₒₜₐₗ=3375 by nesting three layers of amplifying units in a hierarchical configuration, for example, as shown in FIG. 9. The multi-layer strain amplification device that applies the abovementioned hierarchical nested structure is a powerful concept for gaining an order-of-magnitude large amplification of displacement. As a result, the multi-layer strain amplification device 300 shown in FIG. 5 can produce a strain that is at least 20%. This goal can be accomplished by α=15 and K=2: 0.1%×15×15=22.5%. Strictly speaking, the resultant amplification gain is given by the multiplication of each gain:

$${α}_{total} = {\prod }_{k = 1}^{K} {α}_{k} . \qquad ( 7 )$$

where αₖ [symbol] εₖ/εₖ₋₁ is the k-th layer's effective gain of strain amplification computed recursively according to the following formula:

$${ɛ}_{k} = \frac{\sqrt{4 {d}_{k}^{2} - ( {ɛ}_{k - 1}^{2} + 2 {ɛ}_{k - 1} ) {w}_{k}^{2}} - 2 {d}_{k}}{2 {d}_{k} + {h}_{k}} ( k = 1 , … , K ) \qquad ( 8 )$$

FIG. 6 is a three-dimensional schematic view of a multi-layer strain amplification device 400, according to embodiments of the invention. Another important feature of the strain amplification devices and methods of the present invention is that, as described above, two or more planes of rhombi in different layers may be arranged to be perpendicular to each other. Accordingly, in FIG. 6, the multi-layer strain amplification device 400 is formed by serially connecting a plurality of first amplifying layer units 420 to each other, each being rotated 90 degrees about their respective output axes x₁. The first amplifying layer units 420 each comprise at least one actuator unit 401 and a first rhombus structure 422, which is attached to the actuator unit 401. In an embodiment, the actuator unit 401 is a PZT stack actuator. This permits a second rhombus structure 430, which encloses the first amplifying layer units 420, to be more compact, since the length of the first amplifying layer unit 420 in the x₂ direction is reduced. Namely, the height of the actuator unit 401, also shown in FIG. 2 as internal unit 1 having a height h, which is a non-functional dimension for strain amplification, can be reduced. In FIG. 6, a total of two layers, K=2, amplify the strain of the PZT stack actuators. These size reductions permit not only packing many PZT units together densely, but also increase the effective strain along the output axis ε₁, since h₁ is included in the denominator of equation (4) above.

In FIG. 6, six first layer rhombus units 420 are connected in series. As described above, a 3-dimensional structure plays a key role for large strain. Further, as described above, to achieve this, the serially connected units 420 are rotated 90 degrees and inserted into the second rhombus structure 430. Note that the second amplifying layer unit 430 extends in at least one of the x₃, y₃, and z₃ directions when in an ON state, as shown by the arrows, since the PZT stack actuators 401 are extensible and since the number of amplifying layers is 2.

### Properties of Ideal Nested Rhombus PZT Actuators

A. Aggregate Force and Displacement

In an embodiment, displacements of the individual PZT actuators are aggregated and transmitted through multiple layers of strain amplification mechanisms, resulting in an output displacement at the final layer, for example, a final layer comprising the second amplifying layer unit 430 shown in FIG. 6, and a final layer comprising the third amplifying layer unit 540 shown in FIG. 9. Similarly, the output force is the resultant force of many PZT actuators. In this section, these aggregate force and displacement are analyzed in relation to the individual PZT actuator outputs based on an ideal kinematic and static model of the nested rhombus structure.

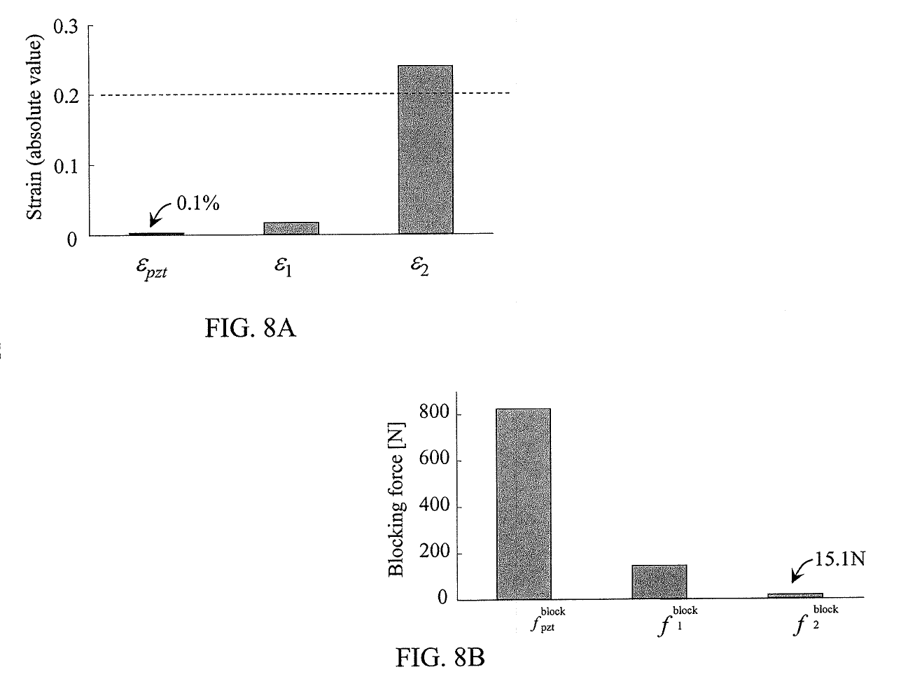

Consider the PZT stack actuator 401 described above with regard to FIG. 7. Let l_{pzt}, w_{pzt}, and h_{pzt} be the length, width, and height of the PZT stack actuator 401, respectively. The x-axis is defined as the actuation direction. Choice of y and z axis is arbitrary. For descriptive purposes, the y axis is chosen to the direction of w_{pzt} as shown in FIG. 8.

The displacement of this PZT stack actuator 401 when no load is connected to the actuator 401 is given by

Δx_{pzt}=N_{film}·d₃₃·V, (9)

where N_{film} is the number of PZT films along the actuation direction, d₃₃ is a piezoelectric coefficient, and V (>0) is a voltage applied to each PZT film. In an embodiment, the piezoelectric coefficient d₃₃ is not a constant, according to A. Mezheritsky, “Invariants of Electromechanical Coupling Coefficients in Piezoceramics,” Ultrasonics, Ferroelectrics, and Frequency Control, IEEE Transactions on, 50(12) pp. 1742-1751, 2003, incorporated herein by reference in its entirety, but may vary significantly as strain gets larger. In this example, however, it is assumed to be constant. The inherent stiffness of the PZT stack actuator 401 is give by

$${k}_{pzt} = \frac{{E}_{pzt} {h}_{pzt} {w}_{pzt}}{{l}_{pzt}} , \qquad ( 10 )$$

where E_{pzt} is the elastic modulus of PZT material.

The no-load displacement given by equation (9) results from the balance between the net force produced by the PZT f_{pzt} and the restoring force due to the stiffness k_{pzt}, which is proportional to Δx_{pzt}. Unlike standard electromagnetic actuators, e.g. DC and AC motors, PZT and other actuator materials cannot produce force independent of its displacement. Due to its inherent structural stiffness, the net output force of these actuator materials is substantially lower when producing a displacement at the same time.

Consider the following force-displacement relationship, the force generated by the PZT stack actuator 401 while producing displacement Δx_{pzt} is given by

f_{pzt}=k_{pzt}(βV−Δx_{pzt}) (11)

where β=N_{film}d₃₃. As this PZT stack is imbedded in a first amplifying layer unit, the force is reduced to 1/α₁ and the displacement is amplified α₁ times. Assuming that the first amplifying layer unit is loss-less and that the beams are completely rigid and are connected with freejoints, the force-displacement relationship at the output axis of the first amplifying layer unit is given by

$${f}_{1} = \frac{{f}_{pzt}}{{a}_{1}} = \frac{{k}_{pzt}}{{a}_{1}} β V - \frac{{k}_{pzt}}{{( {a}_{1} )}^{2}} Δ {x}_{1} \qquad ( 12 )$$

In an embodiment, the equivalent stiffness of the PZT stack viewed from the output side of the rhombus mechanism is attenuated by a factor of 1/(α₁)².

In an embodiment, where N₁ units of the first amplifying layer unit are connected in series and enclosed in a rhombus structure to form a second amplifying layer unit, each unit is numbered from 1 to N₁. Parallel connections in a given layer are not considered since they may form a closed kinematic chain for ideal rhombus mechanisms; thus, solving the kinematic chain problem is not essential. Let Vⁱ, f₁ⁱ, and Δx₁^{j} (i=1, . . . , N₁), respectively, is the voltage, force, and displacement, respectively, of the i-th unit in the serial connection of the first layers. The force is common to all the N₁ units:

f₁¹=f₁²= . . . =f₁^{N} [symbol] f₁^{com} (13)

From (12), we have

$$\frac{{k}_{PZT}}{{a}_{1}} β {V}^{i} - \frac{{k}_{PZT}}{{( {a}_{1} )}^{2}} Δ {x}_{1}^{i} = {f}_{1}^{com} , ( i = 1 , … , {N}_{1} ) . \qquad ( 14 )$$

In an embodiment, where the second amplifying layer unit amplifies displacement and attenuates force α₂ times, the resultant displacement at this layer is given by

$$Δ {x}_{1}^{1} + … + Δ {x}_{1}^{{N}_{1}} = \frac{Δ {x}_{2}}{{a}_{2}} . \qquad ( 15 )$$

From (14) and (15), the relationship between the output force and displacement for the second layer is given by

$${f}_{2} = \frac{{f}_{1}^{com}}{{a}_{2}} = \frac{β {k}_{pzt}}{{N}_{1} {a}_{1} {a}_{2}} {\sum }_{i = 1}^{{N}_{1}} {V}^{i} - \frac{{k}_{pzt}}{{{N}_{1} ( {a}_{1} )}^{2} {( {a}_{2} )}^{2}} Δ {x}_{2} . \qquad ( 16 )$$

Repeating the same process yields the relationship between the aggregate displacement and force along the K-th layer output axis:

$${f}_{K} + \frac{β {k}_{pzt}}{{\prod }_{k = 1}^{K} {a}_{k}} \cdot \frac{1}{{\prod }_{k = 1}^{K - 1} {N}_{k}} {\sum }_{1}^{{N}_{K - 1}} ⋯ {\sum }_{j = 1}^{{N}_{2}} {\sum }_{i = 1}^{{N}_{1}} {V}^{i , j , ⋯} - \frac{{k}_{pzt}}{{\prod }_{k = 1}^{K - 1} {N}_{k} {\prod }_{k = 1}^{K} {( {a}_{k} )}^{2}} Δ xK \qquad ( 17 )$$

A total of N_{K-1}·N_{K-2} . . . N₁ PZT actuator units are included in the system, and V^{i,j} in the above equation represents the voltage applied to the each PZT unit. See, for example, FIG. 5 for K=3 where V^{i,j} is applied to the i-th internal unit in the first player involved in the j-th unit (j=1, . . . , N₂) of the second layer. This process can be repeated as many times needed to attain desired results.

From the above results it is noted that:
1. Given applied voltages, the maximum of the aggregate displacement is obtained when no force is generated, i.e. free load. This aggregate free-load displacement Δx₃^{free} is proportional to the total sum of the inputs

$${\sum }_{1}^{{N}_{K - 1}} ⋯ {\sum }_{1}^{{N}_{2}} {\sum }_{1}^{{N}_{1}} {V}^{i , j , ⋯}$$

amplified by a factor of

$${\prod }_{k = 1}^{K} {a}_{k} ,$$

2. The maximum of the aggregate force is obtained when the output displacement is totally blocked. This aggregate blocking force f_{K}^{block} is proportional to the average of the entire inputs:

$$\frac{1}{{\prod }_{k = 1}^{K - 1} {N}_{k}} {\sum }_{1}^{{N}_{K - 1}} ⋯ {\sum }_{1}^{{N}_{2}} {\sum }_{1}^{{N}_{1}} {V}^{i , j , ⋯} \qquad ( 18 )$$

If the total number of PZT actuators is large, the individual PZT stack actuators can be driven with simple ON-OFF controls, for example, described in Ueda, J., Odhner, L., and Asada, H., “A Broadcast-Probability Approach to the Control of Vast DOF Cellular Actuators,” Proceedings of 2006 IEEE International Conference on Robotics and Automation (ICRA '06), May 15-19, 2006, pp. 1456-1461 and Ueda, J., Odhner, L., and Asada, H., “Broadcast Feedback of Stochastic Cellular Actuators Inspired by Biological Muscle Control,” The International Journal of Robotics Research,” 26(11-12), pp. 1251-1265, 2007, each incorporated herein in its entirety by reference, since the net effect upon the output displacement and force is the summation and average of many PZT actuators. Expensive analog drivers and controllers are unnecessary for the cellular actuators. As the number of PZT actuator cells increases, discretization error becomes small and smooth output displacement and force can be expected.

B. Feasibility Check for at Least 20% Strain

As described above, with regard to FIG. 6, six first-layer actuator units 420 are connected in series. Further, as described above, a three-dimensional structure, as shown in FIG. 6, is important for generating large strain. In an embodiment, the serially-connected first amplifying layer units 420 can be rotated 90 degrees and inserted into the second rhombus structure 430. Accordingly, the second rhombus structure 430 extends when the PZT actuators are turned on since they are extensible and the number of amplifying layers is two.

In an embodiment, to achieve a strain of 23.9%, a size of each actuator unit 401 is approximately 12.8 mm (l_{pzt} shown in FIG. 7)×9 mm (w_{pzt} shown in FIG. 7)×2.5 mm (h_{pzt} shown in FIG. 7). In an embodiment, an initial gap d₁ between the surface of the PZT stack actuator 401 and the apex of a rhombus structure 422 of the first amplifying layer unit 420 is approximately 1.1 mm. Further, typical values of PZT-ceramics for Young's modulus and strain can be applied, i.e., E_{pzt}=36.6 GPa and ε_{pzt} (=ε₀)=0.1%, respectively. In an embodiment, these dimensional parameters are determined according to commercially available PZT actuators, for example, Cedrat APA50XS, as being a first layer unit. In an embodiment, the size of the multi-layer strain amplification device 400 shown in FIG. 6 is 12.0 mm×28.2 mm×12.8 mm.

As shown in FIG. 8A, a typical value of PZT ceramics for strain is 0.1%. However, by performing iterative calculations by applying equations (12)-(16) above, the amplified strain and reduced blocking force are obtained as shown in FIGS. 8A and 8B. In particular, the prospective displacement is 2.8 mm for an actuator length of 12 mm, which is equivalent to ε₂=23.9%. Thus, over 20% strain is achieved by the amplification device.

Furthermore, it should be noted that diverse configurations can be built simply by changing the serial and parallel arrangements of the same building blocks. This modular design is a powerful method for building diverse actuators with matched load impedance and stroke and force requirements. As a result, as shown in FIG. 8A, the multi-layer strain amplification device 400 can produce an amplified strain ε₂ of at least 20% (specifically, 23.9%) as compared to the strain ε_{pzt} of PZT stack actuator 401 (0.1%) and the strain ε₁ of a first amplifying layer unit 420. In addition, as shown in FIG. 8B, the multi-layer strain amplification device 400 can produce a lower blocking force f₂^{block} of 15.1N as compared to the blocking force f_{pzt}^{block} of PZT stack actuator 401 and the blocking force f₁^{block} of a first amplifying layer unit 422.

FIG. 9 is a three-dimensional view of a three-layer strain amplification device 500, according to embodiments of the invention. In FIG. 9, the three-layer strain amplification device 500 is formed by serially connecting a plurality of first amplifying layer units 520 to each other, each first amplifying layer units 520 comprising an actuator unit 501 and a first rhombus structure 522. A second rhombus structure 530 is positioned about the first amplifying layer units 520 to form a second amplifying unit. A third rhombus structure 540 is positioned about a plurality of second amplifying layer units to form the three-layer strain amplification device 500, which, in an embodiment, has a strain of at least 30%.

Effects of Joint Stiffness and Beam Compliance

As described above, a nested Rhombus PZT actuator can produce an effective strain of at least 20% and a blocking force of approximately 15N. In an embodiment, these parameters are based on an ideal kinematic model having rigid beams and free joints at the strain amplification mechanism. Actual mechanisms, however, have some compliance in the structure, which may degrade the aggregate force and displacement. For example, intricate interplays between the structural stiffness and the inherent stiffness of the actuator units, for example, PZT stack actuators, can exist in the mechanism. Thus, in an embodiment, the nested strain amplification mechanism can be configured to minimize this adverse effect.

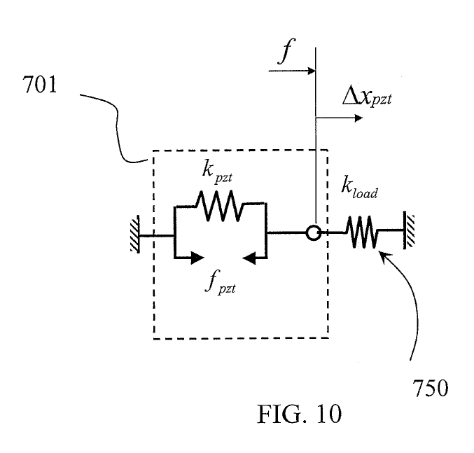

FIG. 10 is a diagram illustrating a model of an actuator unit 701 connected to a spring load 750, according to embodiments of the invention. In an embodiment, the model shown in FIG. 10 demonstrates the potential of a multi-layer strain amplification device, for example, the device shown in FIG. 6, to produce an effective strain of 20% with a blocking force of 15 N. Let k_{load} be a spring constant of the load 750, and Δx_{pzt} be the displacement of the load 750. The following equations hold:

f_{pzt}=(k_{load}+k_{pzt})Δx_{pzt} (19)

f=k_{load}Δx_{pzt}, (20)

where f is the output force applied to the load. The free-load displacement Δx_{pzt}^{free} is calculated by letting k_{load}=0.
Eliminating Δx_{pzt} yields

$$f = \frac{{k}_{load}}{{k}_{pzt} + {k}_{load}} {f}_{pzt} \qquad ( 21 )$$

Note that the output force f becomes significantly lower than the original PZT force f_{pzt} when k_{pzt} increases the load stiffness k_{load} is reduced. Similarly, the output displacement Δx_{pzt}, too, gets attenuated:

$$Δ {x}_{pzt} = \frac{{k}_{pzt}}{{k}_{pzt} + {k}_{load}} Δ {x}_{pzt}^{free} \qquad ( 22 )$$

The simple model described above shows that both output force and displacement are attenuated due to the compliance of the connected load as well as the stiffness of the PZT itself. When this PZT stack actuator 701 is connected to a multi-layer strain amplification device, an external load 750 having properties similar to the above k_{load} and k_{pzt} will be imposed on the PZT stack actuator 701. As many layers of the amplification device are attached to the PZT stack actuator 701, these structural effects will be even more prominent. In the ideal mechanism, for example, shown in FIG. 4, it is assumed that the four beams 722 of the rhombus-type structure 720 are completely rigid and that all the joints are free to rotate and purely revolving. However, these assumptions do not hold in real structures.

Further, fabrication of free joints is difficult in small scale due to mechanical tolerance and play. For the first and second layers of the multi-layer strain amplification device, in particular, where the displacement is extremely small, the displacement created by the PZT is likely to diminish due to the play at the joints. Therefore, flexural pivots and flexible beams, such as those described in N. Conway, and S. Kim, “Large-strain, piezo-electric, in-plane, micro-actuator,” 17^{th} IEEE International Conference on Micro Electro Mechanical Systems (IEEEM MEMS), pp. 454-457, 2004, N. Conway, and S. Kim, and Z. Traina, “A Strain Amplifying Piezoelectric MEMS Actuator,” Journal of Micromechanics and Microengineering, 17(4), pp. 781-787, 2007, Cedrat, Inc., http://www.cedrat.com/, and P. Jenker, M. Christmann, F. Hermle, T. Lorkowski, and S. Storm, Mechatronics Using Piezoelectric Actuators,” Journal of the European Ceramics Society, 19(6), pp. 1127-1131, 1999, each incorporated herein in its entirety by reference, have been used for amplifying PZT displacement. FIG. 3 shows an example embodiment of a rhombus mechanism. However, these flexural joints and beams inevitably bring undesirable properties to the multi-layer strain amplification device. There are three types of undesirable properties:

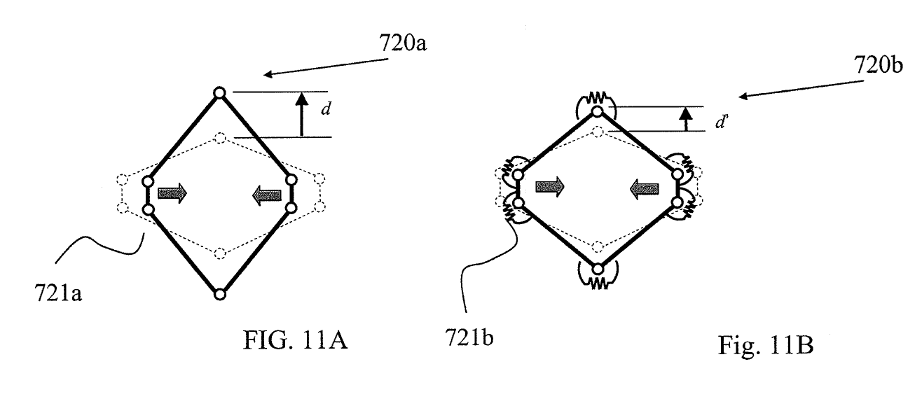

First, the joints are no longer free joints, but they impose a spring load that a PZT has to overcome. FIGS. 11A and 11B are illustrative views of a rhombus illustrating this parasitic effect of joint stiffness on free-load displacement, according to embodiments of the invention. In particular, FIG. 11A is an illustration of an ideal rhombus 720a comprising rigid beams and free joints 721a. FIG. 11B is an illustration of a rhombus 720b comprising rigid beams and elastic joints 721b. Accordingly, some fraction of the PZT force is wasted for coping with the joint stiffness. This results in, for example, a reduction in free-load displacement, as indicated in the difference between gap d shown in FIG. 11A and gap d′ shown in FIG. 11B. This implies that the joint stiffness has an equivalent effect to that of the PZT stiffness k_{pzt} in FIG. 10. The stiffness of the joints results in a corresponding increased stiffness k_{pzt} for the PZT to overcome.

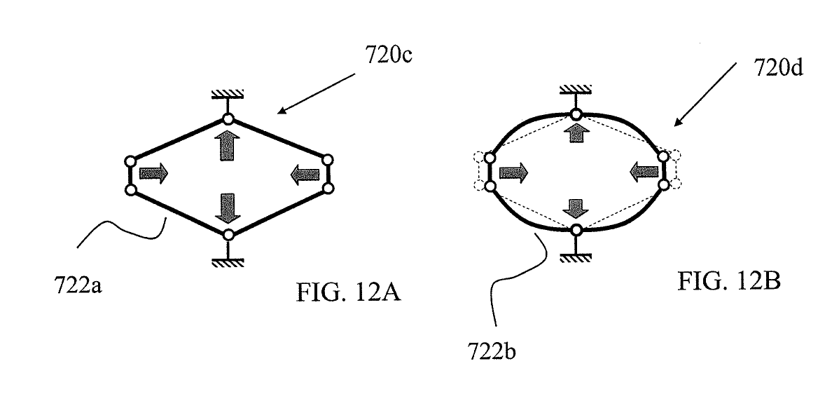

Second, flexibility at the beams may attenuate the displacement and force created by the PZT. Consider the case where the output displacement is blocked, as shown in FIGS. 12A and 12B. As the PZT generates a displacement, the beams 722b of the rhombus 720d shown in FIG. 12B are deformed and thereby the transmitted force becomes lower; at least it does not reach the same level as that of the rigid beams 722a of the rhombus 720c shown in FIG. 12A. Similarly, if the output axis is coupled to another compliant load, the output force and displacement will be prorated between the load compliance and the beam compliance. As the beam stiffness becomes lower, the output force and displacement decrease.

Third, flexural joints not only create pure rotational displacements but also often cause unwanted translational displacements. These elastic deformations at the joint along the direction of the beam incur the same problem as the beam compliance; the force and displacement created by the PZT tend to diminish at the joints.

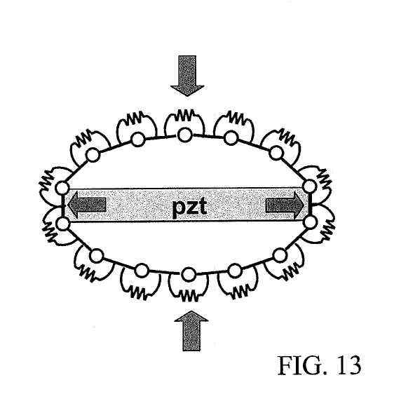

It is important to distinguish two different types of compliance in the above cases. The first type of compliance occurs in the constrained space of the ideal rhombus mechanism. The second type of compliance occurs in a kinematically admissible space of the ideal rhombus mechanism. The joint stiffness described above with regard to the first property is in the admissible motion space, while the second and third properties are in the constrained space. As shown in FIG. 13, curved beams, such as those provided in Moonies, contain compliance in both constrained and admissible spaces. The distributed compliance can be approximated into the two types of lumped compliant elements. To minimize the adverse effects of the nested rhombus structure, the stiffness in the admissible space must be minimized and the stiffness in the constrained space must be maximized. Accordingly, as multiple layers of strain amplification devices can be used, the compliances in the admissible and constrained spaces become more intricate.

In the following sections, the kinematic and static characteristics of multi-layer compliant rhombus mechanisms will be analyzed.

Nested Rhombus Mechanisms with Structure Flexibility

A. Modeling of Single-Layer Flexible Rhombus Mechanisms

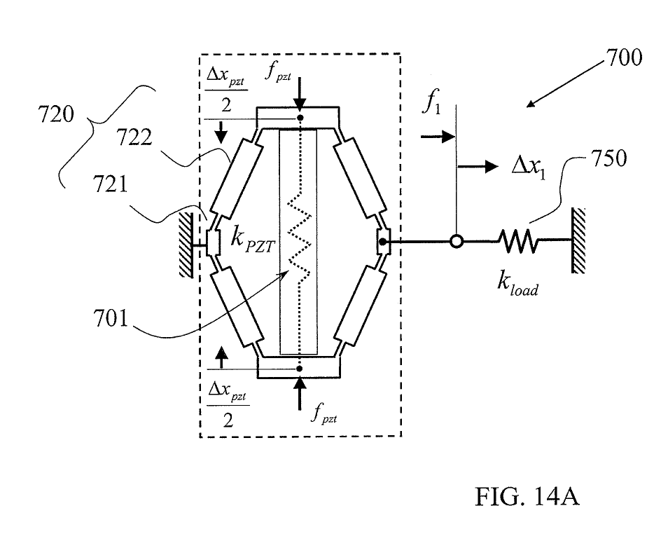

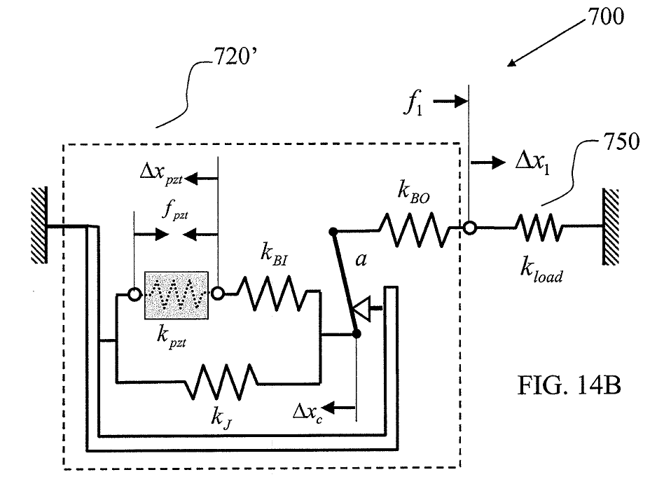

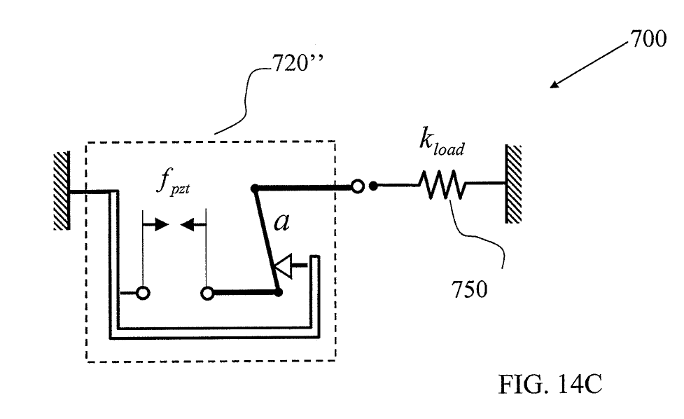

FIG. 14A illustrates a rhombus structure 720 of an amplification mechanism 700 that is connected to a spring load 750. In an embodiment, the rhombus structure 720 comprises at least one Moonie. Here, only the static case is considered and the effect of the distribution of mass and damper is neglected. In FIG. 14A, k_{load} is elastic modulus of the load and k_{pzt} is the elastic modulus of the internal unit 701, for example, a PZT stack actuator, Δx_{pzt} is the displacement of the internal unit 701, f_{pzt} is the force applied to the amplification mechanism 700 from the internal unit 701, f₁ is the force applied to the load from the actuator, and Δx₁ is the displacement of the load. In an embodiment, the internal unit 701 is extensible.

In an embodiment, the rhombus strain amplification mechanism 700 is a two-port compliance element, whose constitutive law is given by a 2×2 stiffness matrix defined as:

$$[ \begin{matrix}{f}_{l} \\ {f}_{o}\end{matrix} ] = S [ \begin{matrix}Δ {x}_{pzt} \\ Δ {x}_{1}\end{matrix} ] \qquad ( 23 )$$

where

$${S}^{2 \times 2} = [ \begin{matrix}{s}_{1} & {s}_{3} \\ {s}_{3} & {s}_{2}\end{matrix} ]$$

is a stiffness matrix, f₁ is the net force applied to the mechanism 700 from the internal unit 701, and f₀ is the reaction force from the external load 750. The stiffness matrix S is non-singular, symmetric, and positive-definite; s₁>0, s₂>0 and s₁s₂-s₃²>0.

The symmetric nature of the stiffness matrix follows Castigliano's theorems. When the input port of this mechanism is connected to a PZT stack actuator producing force f_{pzt} with inherent stiffness k_{pzt} and the output port is connected to a load of stiffness k_{load}, we have

f_{I}=f_{pzt}−k_{pzt}Δx_{pzt}=s₁Δx_{pzt}+s₃Δx₁ (24)

f_{O}=−f₁=−k_{load}Δx₁=s₃Δx_{pzt}+s₂Δx₁ (25)

Eliminating Δx_{pzt} from the above equations yields:

$${f}_{pzt} = - ( \frac{{k}_{pzt } + {s}_{1}}{{s}_{3}} {k}_{load} + \frac{{s}_{2} ( {k}_{pzt} + {s}_{1} ) - {s}_{3}^{2}}{{s}_{3}} ) Δ {x}_{1} \qquad ( 26 )$$

Defining:

$$\begin{matrix}\tilde{f} {=}^{Δ} \frac{- {s}_{3}}{{k}_{pzt} + {s}_{1}} {f}_{pzt} & ( 27 ) \\ \tilde{k} {=}^{Δ} \frac{{s}_{2} ( {k}_{pzt} + {s}_{1} ) - {s}_{3}^{2}}{{k}_{pzt} + {s}_{1}} = \frac{{s}_{2} {k}_{pzt} + det S}{{k}_{pzt} + {s}_{1}} > 0 , & ( 28 )\end{matrix}$$

The above equation (26) reduces to

\tilde{f}=(k_{load}+\tilde{k})Δx₁ (29)

Force \tilde{f} and stiffness \tilde{k} represent the effective PZT force and the resultant stiffness of the PZT stack all viewed from the output port of the amplification mechanism 700.

A drawback with the above two-port model representation is that it is hard to gain physical insights as to which elements degrade actuator performance and how to improve it through design. In the previous section two distinct compliances were introduced, one in the admissible motion space and the other in the constrained space. To improve performance with respect to output force and displacement, the stiffness in the admissible motion space must be minimized, while the one in the constrained space must be maximized. To manifest these structural compliances, consider a lumped parameter model 720′ shown in FIG. 14B with three spring elements, k_{J}, k_{BI} and k_{BO}, and one amplification leverage α. As the spring constants, k_{BI} and k_{BO}, tend to infinity, the system reduces to the one consisting of all rigid links, where the output Δx₁ is directly proportional to the input displacement Δx_{pzt}. Stiffness k_{J} impedes this rigid body motion, representing the stiffness in the admissible motion space. Elastic deformation at k_{BI} and k_{BO} represent deviation from the rigid body motion.

From FIG. 14B,

f_{pzt}+k_{BI}(Δx_{c}−Δx_{pzt})−k_{pzt}Δx_{pzt}=0 (30)

α·k_{BO}(α·Δx_{c}−Δx₁)+k_{J}Δx_{c}+k_{BI}(Δx_{c}−Δx_{pzt})=0 (31)

f₁=k_{load}Δx₁=k_{BO}(α·Δx_{c}−Δx₁) (32)

where Δx_{c} is the displacement at the connecting point between the leverage and springs; however this point is virtual and Δx_{c} does not correspond to a physical displacement. This model is applicable to a wide variety of “rhombus-type” amplification mechanisms including Moonies.

Consider the blocking force when the PZT stack actuator 701 generates its maximum force, f_{pzt max}, given as follows:

$${f}_{1}^{block} = \frac{{ak}_{BI} {k}_{BO}}{( {a}^{2} {k}_{BI} {k}_{BO} + {k}_{BI} {k}_{J} ) + {k}_{pzt} ( {a}^{2} {k}_{BO} + {k}_{J} + {k}_{BI} )} {f}_{pzt max} \qquad ( 33 )$$

Similarly, the free-load displacement for this rhombus mechanism, where k_{load}→0, is given by

$$Δ {x}_{1}^{free} = \frac{{ak}_{BI}}{{k}_{pzt} ( {k}_{BI} + {k}_{J} ) + {k}_{J} {k}_{BI}} {f}_{pzt max} \qquad ( 34 )$$

As addressed above, these equations imply that the blocking force will be maximized by kBI,kBO→∞. Similarly, kJ→0 maximizes Δx₁^{free}.

The other advantage is that the three-spring model is able to represent the ideal rhombus shown in FIG. 12A as a special case 720″ as shown in FIG. 14C. See equation (47) to confirm that the stiffness matrix S cannot be defined for both k_{BI},k_{Bo}→∞ and k_{J}→0. As described in below, the four unknown parameters occur as the rigid amplification leverage is explicitly included, which makes the calibration problem ill-posed. However, this amplification leverage is necessary to include the ideal case. In addition, three lumped springs are considered minimum to satisfy the input-output bidirectionality, which is a basic requirement of Castigliano's theorems described herein.

B. Model Simplification

From equations (30) to (32), the relationship between f_{pzt} and Δx₁ is given by

(αk_{BI}k_{BO})f_{pzt}=

[k_{load}{α²k_{BI}k_{BO}+k_{BI}k_{J}+k_{pzt}(α²k_{BO}+k_{J}+k_{BI})}

+k_{BO}(k_{BI}k_{J}+k_{pzt}k_{J}+k_{BI}k_{pzt})]Δx₁. (35)

The above equation can be written as

$$\begin{matrix}\tilde{f} i = ( {k}_{load} + {\tilde{k}}_{1} ) Δ {x}_{1} \\ where & ( 36 ) \\ {\tilde{k}}_{1} {=}^{Δ} \frac{{k}_{BO} ( {k}_{BI} {k}_{J} + {k}_{pzt} {k}_{J} + {k}_{BI} {k}_{pzt} )}{( {a}^{2} {k}_{BI} {k}_{BO} + {k}_{BI} {k}_{J} ) + {k}_{pzt} ( {a}^{2} {k}_{BO} + {k}_{J} + {k}_{BI} )} & ( 37 ) \\ {\tilde{f}}_{1} {=}^{Δ} \frac{{ak}_{BI} {k}_{BO}}{( {a}^{2} {k}_{BI} {k}_{BO} + {k}_{BI} {k}_{J} ) + {k}_{pzt} ( {a}^{2} {k}_{BO} + {k}_{J} + {k}_{BI} )} {f}_{pzt} & ( 38 )\end{matrix}$$

This implies that the proposed lumped parameter model shown in FIG. 14B can be further simplified in the model 720′″ shown in FIG. 15. Note that the direction of \tilde{f}₁ is opposite to f_{pzt} due to the amplification leverage. This simplified model has a similar form as in equation (29) above. As described in the following section, this simplification enables performance evaluation for complex nested mechanisms simply by nesting a simplified model of lower layers into a lumped parameter model. As a result, the performance of the overall mechanism such as aggregate displacement and force can be predicted in a recursive manner.

In another embodiment, a free-load displacement with known k_{pzt} can be determined as follows to calculate for f_{pzt} and x₁:

$$\begin{matrix}{f}_{pzt} = \frac{{k}_{PZT} ( {k}_{BI} + {k}_{J} ) + {k}_{J} {k}_{BI}}{{ak}_{BI}} {x}_{1} & ( 39 ) \\ {x}_{1} = \frac{{ak}_{BI}}{{k}_{PZT} ( {k}_{BI} + {k}_{J} ) + {k}_{J} {k}_{BI}} {f}_{pzt} & ( 40 )\end{matrix}$$

C. Recursive Formula of Aggregate Force and Displacement of Flexible Nested Mechanisms

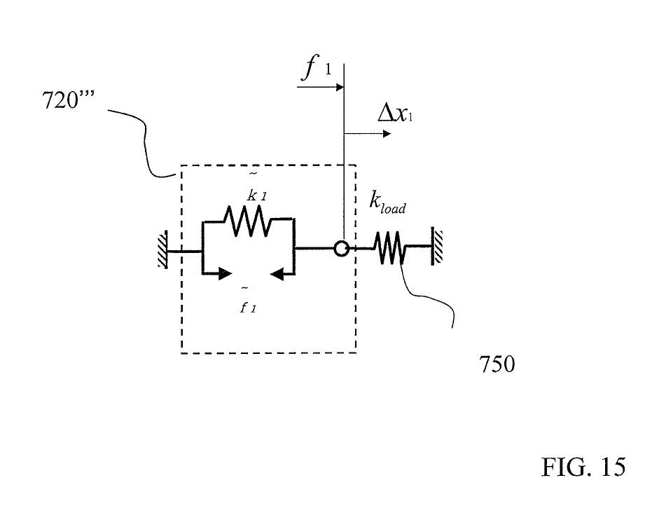

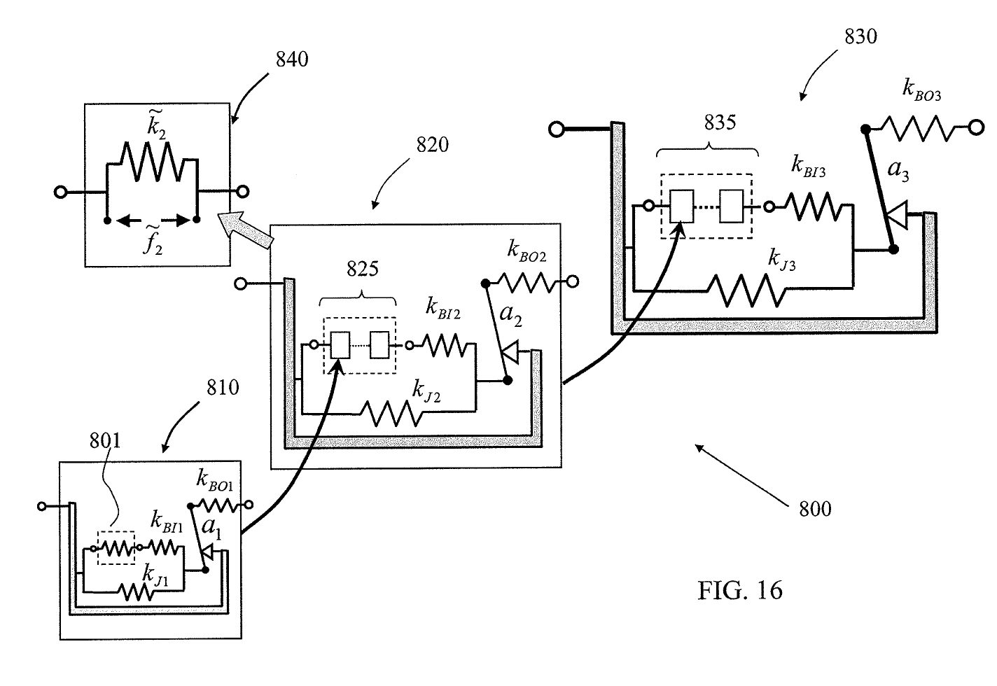

The following describes a recursive formula to obtain an equivalent model for a general nested mechanism. FIG. 16 is a multi-layer strain amplification device 800 having a nested rhombus structure in accordance with embodiments of the invention. As addressed in the previous sections, each nested layer 810, 820, 830 can be represented by its equivalent model, for example, equivalent model 840, where the force-displacement property for the nested structure can be represented in an iterative manner. Let K be the number of nesting layers. Also, let k_{Jk}, k_{BIk}, k_{BOk}, Nₖ be the joint compliance, beam compliances, and the number of serial connection for the k-th (k=1, . . . K) layer. This mechanism involves N_{K-1}·N_{K-2} . . . N₁ PZT stack actuators. N₂ refers to a plurality of serially connected internal units or stack actuators 825. N₃ refers to a plurality of serially connected internal units or stack actuators 835. By applying equations (37) and (38), the equivalent model for the k-th layer can be represented by

$$\begin{matrix}{\tilde{k}}_{k} = \frac{{k}_{BOk} ( {k}_{BIk} {k}_{Jk} + \frac{{\tilde{k}}_{k - 1}}{{N}_{k - 1}} {k}_{Jk} + {k}_{BIk} {k}_{pztk} )}{( {a}_{k}^{2} {k}_{BIk} {k}_{BOk} + {k}_{BIk} {k}_{Jk} ) + \frac{{\tilde{k}}_{k - 1}}{{N}_{k - 1}} ( {a}_{k}^{2} {k}_{BOk} + {k}_{Jk} + {k}_{BIk} )} & ( 41 ) \\ {\tilde{f}}_{k} = \frac{{a}_{k} {k}_{BIk} {k}_{BOk}}{( {a}_{k}^{2} {k}_{BIk} {k}_{BOk} + {k}_{BIk} {k}_{Jk} ) + \frac{{\tilde{k}}_{k - 1}}{{N}_{k - 1}} ( {a}_{k}^{2} {k}_{BOk} + {k}_{Jk} + {k}_{BIk} )} \times \frac{1}{{N}_{k - 1}} {\sum }_{i = 1}^{{N}_{k - 1}} {\tilde{f}}_{k - 1}^{i} , & ( 42 )\end{matrix}$$

where

$${f}_{k - 1}^{∼ i}$$

is the equivalent force of the i-th unit in the (k−1)-th layer. Recall that \tilde{f}ₖ is proportional to the average of the entire forces at the (k−1)-th layer as described above in equation (18). Assume that all actuators in the (k−1)-th layer are controlled in a binary manner, i.e.,

$${v}_{k - 1}^{i} = \{ \begin{matrix}{V}_{max} & ON \\ 0 & OFF\end{matrix} \qquad ( 43 )$$

Also assume that all units are uniform and each unit generates \tilde{f}ₖ₋₁^{block} as its blocking force. Therefore, when n units out of Nₖ₋₁ actuators are ON, the last term of equation (42) can be replaced as

$$\frac{1}{{N}_{k - 1}} {\sum }_{i = 1}^{{N}_{k} - 1} {\tilde{f}}_{k - 1}^{i} -> \frac{n}{{N}_{k - 1}} {\tilde{f}}_{k - 1}^{block} \qquad ( 44 )$$

In an embodiment, the free-load displacement changes accordingly. In an embodiment, both the aggregate free-load displacement and the blocking force are proportional to the number of ON units.

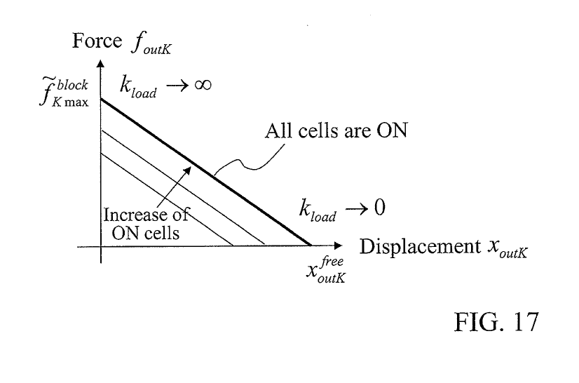

Accordingly, as shown in FIG. 17, a force-displacement relationship is provided when N cells are in an ON position.

### Mechanical Design of Amplification Mechanism

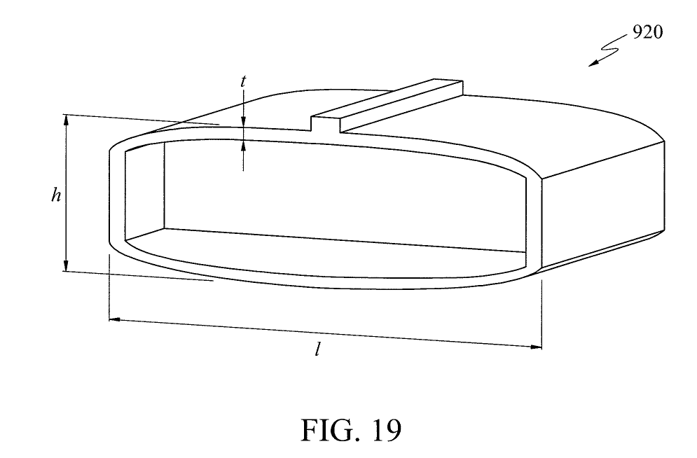

In an embodiment, a nested actuator with over 20% effective strain can be designed based on the structural compliance analysis above. Consider a nested structure with two amplification layers as described above with regard to FIG. 6. In an embodiment, the actuator 920 shown in FIG. 19 can be a prototype nested actuator, for example, a Cedrat APA50XS Moonie piezoelectric actuator, which can be used in a first amplifying layer unit such as the first amplifying layer unit described in FIG. 3. According to the preliminary design described above, over 20% of effective strain can be obtained by a two-layer mechanism; K=2 and α=15. By stacking 6 APA50XS actuators for the first layer, i.e., N₁=6, this large strain may be achieved with a proper design of the second layer. From Table 1, we have \tilde{k}₁=0.225×106 N/m, and f₁^{\tilde{b}\tilde{l}ock}=18.0 N for the first layer units. The remainder of this section focuses on the design of the second-layer rhombus mechanism.

From equations (39) and (40) we obtain an equivalent model for the second layer by substituting equations (37) and (38), which provide a design guideline in terms of k_{BI2}, k_{BO2} and k_{J2} for the target effective strain, i.e., 20%.

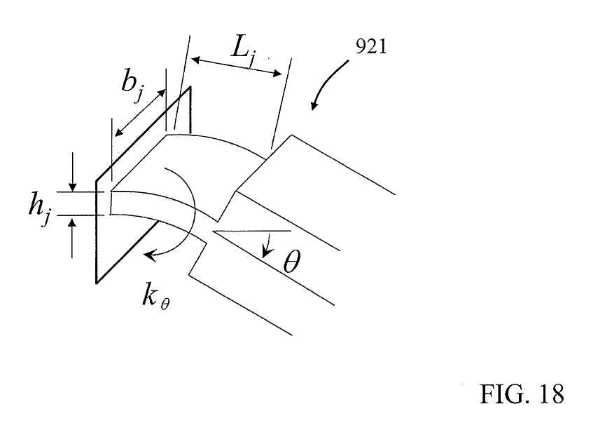

FIG. 18 is an illustration of a compliant joint 921 for an amplifying layer unit, according to embodiments of the invention. As described above, the stiffness in the admissable space, i.e., k_{J2}, must be minimized. The rotational stiffness of this structure is given by

$${k}_{φ} = \frac{{Eb}_{J} {h}_{J}^{3}}{12 {L}_{J}}$$

where E is Young's modulus of the material. In order to reduce this stiffness, either the width b_{J} or thickness h_{J} must be reduced, or length of the gap L_{J} must be increased. Note that the reduction of h_{J} is the most effective for reducing k_{J2} since it is proportional to h_{3J}. However, the thickness must be carefully determined considering manufacturing process. The maximum stress must be lower than the yield stress of material. In addition, in order to increase the stiffness in the constrained space, i.e., k_{BI2} and k_{BO2}, the oblique beam need to have a sufficient thickness except the thin part for the compliant joint 921.

In an embodiment, the actuator 920 shown in FIG. 19 can be a prototype nested actuator, for example, a Cedrat APA50XS Moonie piezoelectric actuator, which can be used in a first amplifying layer unit such as the first amplifying layer unit described in FIG. 3.

Table 1 below includes characteristics of the Cedrat APA50XS Actuator, described above, details of which can be found at www.cedrat.com, last downloaded on Oct. 24, 2007, incorporated by reference above. The results shown in Table 1 can be modified as a result of incorporating embodiments of the invention described herein.

TABLE 1

| | | |
|---|---|---|
| Displacement | 80 | μm |
| Blocking Force \tilde{f}₁^{block} | 18.0 | N |
| Stiffness \tilde{k} | 0.225 | N/μm |
| Voltage range | −20-150 | V |
| Length (output actuation direction) | 4.7 | mm |
| Width (pzt stack actuation direction) | 12.8 | mm |
| Height | 9.0 | mm |
| Mass | 2.0 | g |

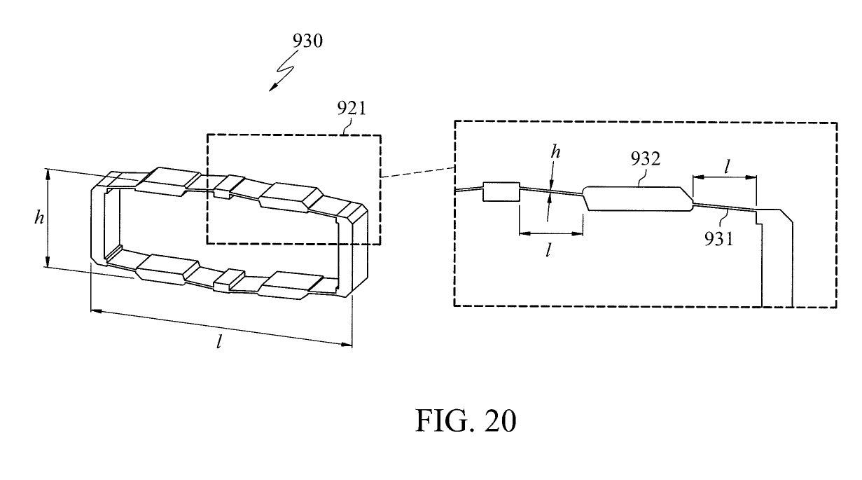

FIG. 20 is an illustration of a second layer rhombus structure 930, according to embodiments of the invention. In an embodiment, the structural parameters for the second layer rhombus structure 930 are obtained as k_{J2}=0.0402 N/μm, k_{B2}=0.051N/μm, and α₂=11.23. The second layer rhombus structure 930 also includes joint 921 similar to the joint shown in FIG. 18 having dimensions including a length (l) and height (h). In an embodiment, the second layer rhombus structure 930 shown in FIG. 20 can have a length (l) of approximately 30 mm and a height (h) of approximately 12 mm. In an embodiment, the minimum thickness h_{J} of joint 931 is approximately 0.1 mm for electrical discharging. In an embodiment, a length L_{J} of the joint 931 between beams 932 is approximately 3.5 mm. In an embodiment, the oblique beams 932 have a thickness of approximately 1.3 mm for sufficient stiffness. In an embodiment, the oblique angle of the beams 932 is approximately 4.97 degrees that gives the displacement amplification ratio of approximately 11.5 assuming the mechanism is ideal.

In an embodiment, the parameters for the lumped parameter model are therefore calculated using the calibration method described herein as \hat{k}_{BI2}=6.72×106 N/m, \hat{k}_{BO2}=5.21×104 N/m, \hat{k}_{BJ2}=3.98×104 N/m by determining the amplification gain as \hat{α}₂=11.4.

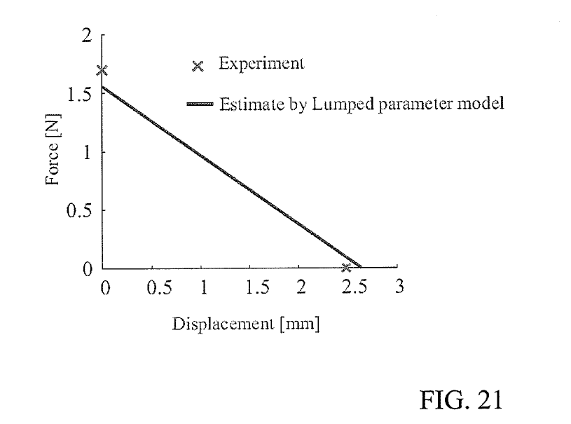

FIG. 21 is a graph illustrating a calculated force and displacement property of the second layer rhombus structure of FIG. 20, according to embodiments of the invention. The analysis herein predicts that the maximum free-load displacement is 2.64 mm, which is equivalent to 22% effective strain.

### Development and Performance Evaluation

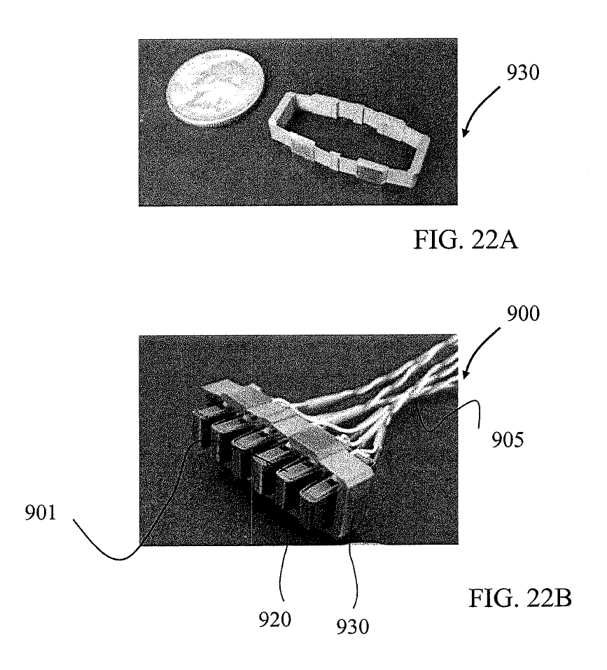

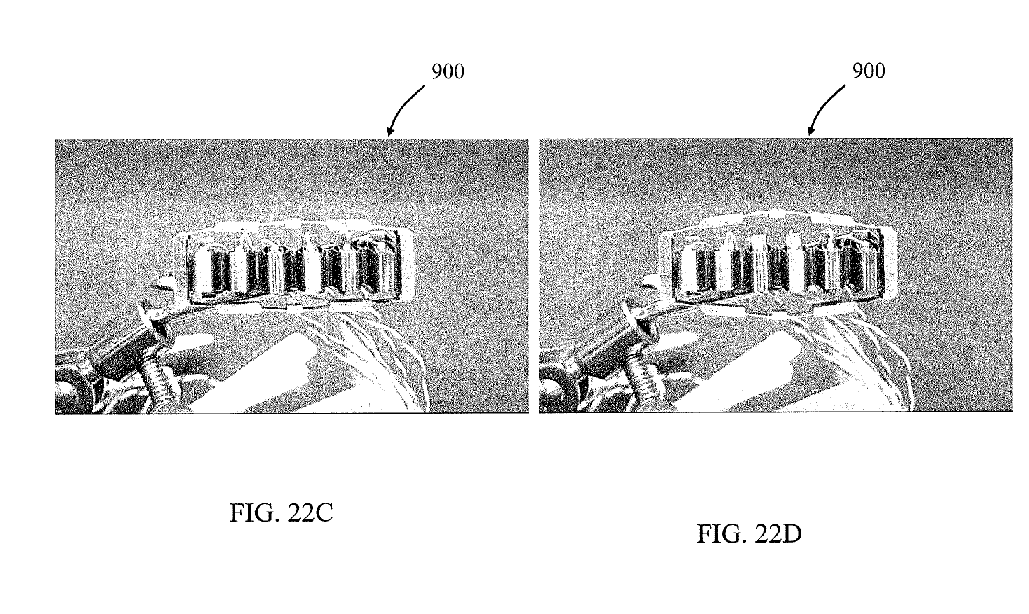

FIG. 22A is an illustration of a second layer rhombus structure 930, according to embodiments of the invention. FIG. 22B is an illustration of an amplification device 900 having two amplification layers, wherein one of the amplification layers comprises the second layer rhombus structure 930 of FIG. 22A, according to embodiments of the invention. In particular, FIG. 22A shows a second layer rhombus structure 930, which can be configured as part of a second layer of a multi-layer strain amplification device, such as the assembled multi-layer strain amplification device 900 shown in FIG. 22B. The serially connected first layer units 920, which amplify the strain of PZT stack actuators 901 powered from the wires 905, are rotated 90 degrees and inserted into the second layer rhombus structure 930. In an embodiment, the second layer rhombus structure 930 weighs approximately 3 g. In another embodiment, the device 900 weighs approximately 15 g. In an embodiment, phosphor bronze (C54400, H08) is applied for material used to form the device 900. FIGS. 22C and 22D are views of the second layer rhombus structure of FIG. 22A in OFF and ON positions, according to embodiments of the invention.

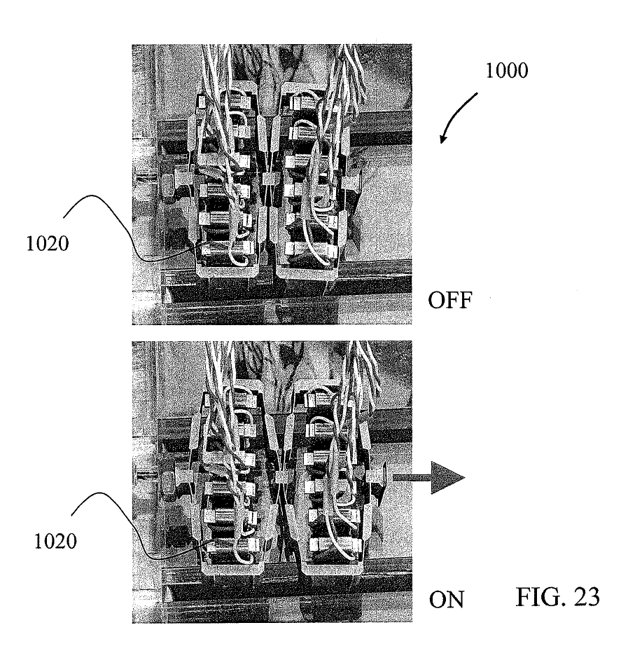

FIG. 23 is a view of two amplification mechanisms 1000 connected in series, and in OFF and ON positions, respectively, according to embodiments of the invention. In an embodiment, the amplification mechanisms 1000 are configured as an actuator, wherein the actuator extends when first layer units 1020 of the amplification mechanisms 1000 are in a contractive state.

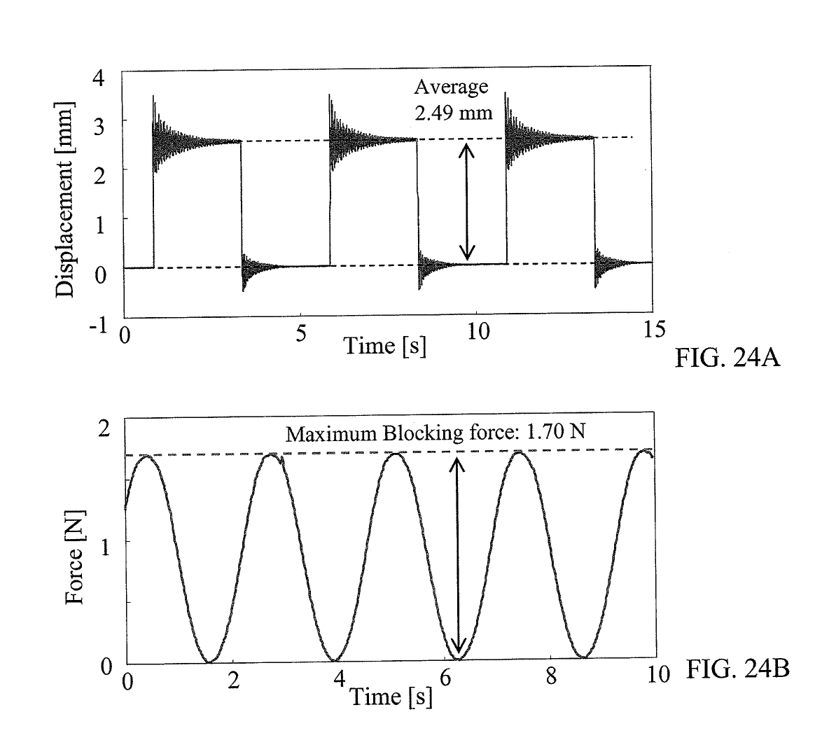

The performance of an actuator, such as the actuators shown in FIGS. 22B and 23, can be evaluated by measuring free-load displacement and blocking force. FIG. 24A shows the maximum free-load displacement measured using a laser displacement sensor, for example, a Micro-Epsilon optoNCDT 1401 sensor, when all six first layer units are ON by applying 150V actuation voltage. The measured displacement is 2.49 mm that is equivalent to 20.8% effective strain. FIG. 24B shows the blocking force where a sinusoidal wave input ranging from 0-150V is applied. The maximum blocking force measured using a compact load cell (Transducer Techniques MLP) is 1.7N. As shown in FIGS. 24A and 24B, the estimated values by using the lumped parameter model agree well with the experiment, which confirms the validity of the approach taken in accordance with embodiments described herein.

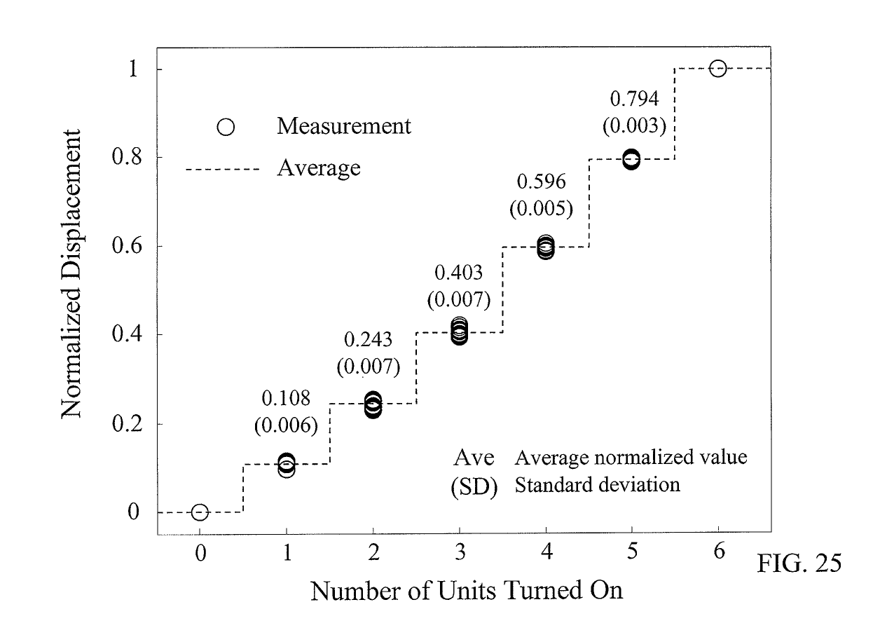

FIG. 25 is a graph showing aggregate displacements when ON-OFF controls are provided to six internal units by applying a constant actuation voltage when ON, in accordance with embodiments of the invention. For convenience, the measured displacements are normalized by the maximum displacement when all six units are turned on. As described in herein, the distribution of the ON units in a layer does not theoretically affect on the aggregate displacement if an amplification mechanism encloses serially-connected internal units. As shown in FIG. 25, the measured displacement is not largely affected by the combination of ON units. For example, there are twenty (=₆C₃) combinations when the number of ON units is three; however, the standard variation is at most 0.007, showing a sufficient repeatability. Another observation is that the increment of the displacement is not uniform, which is considered due to the nonlinearity of equation (1). In the preliminary kinematic analysis described above, this issue is not discussed for simplicity. However, this characteristic should be further reflected to the design and control if rhombus mechanisms are used for creating large strain.

The comparison between FIG. 8 and FIG. 21 suggests that the aggregated force has been considerably attenuated, while the aggregated displacement or strain is as large as predicted by the idealized analysis. One of the difficulties in mechanical design is that physical structural parameters are intricately related to lumped parameters. For example, the increase of the gap L_{J} in FIG. 18 contributes to reducing the joint stiffness but it also reduces the beam stiffness by having a long thin gap in the longitudinal direction. This gap may be reduced if the design focus is more on producing a larger blocking force.

### Modular Design of Cellular Actuators

In accordance with embodiments of the present invention, an architecture for robot actuators is provided that is inspired by the muscle behavior, which in turn has the potential to be a novel approach to controlling of a vast number of cellular units, for example, described in J. Ueda, L. Odhnar, and H. Asasa, “A broadcast-probability approach to the control of vast dof cellular actuators,” Proceedings of 2006 IEEE International Conference on Robotics and Automation (ICRA '06), May 15-19, 2006, pp. 1456-1461, Ueda, J., Odhner, L., and Asada, H., “Broadcast Feedback of Stochastic Cellular Actuators Inspired by Biological Muscle Control,” The International Journal of Robotics Research,” 26(11-12), pp. 1251-1265, 2007, and J. Ueda, L. Odhner, and H. Asada, “Broadcast Feedback for Stochastic Cellular Actuatory Systems consisting of Nonuniform Actuator Units,” In Proceedings of 2007 IEEE International Conference on Robotics and Automation (ICRA '07), pp. 642-647, 2007, each incorporated by reference above. Instead of wiring many control lines to each individual cells, each cellular actuator has a stochastic local control unit that receives the broadcasted signal from the central control unit, and turn its state in a simple ON-OFF manner as described above. A wide variety of sizes and shapes is configurable using the designed actuator as a building-block.

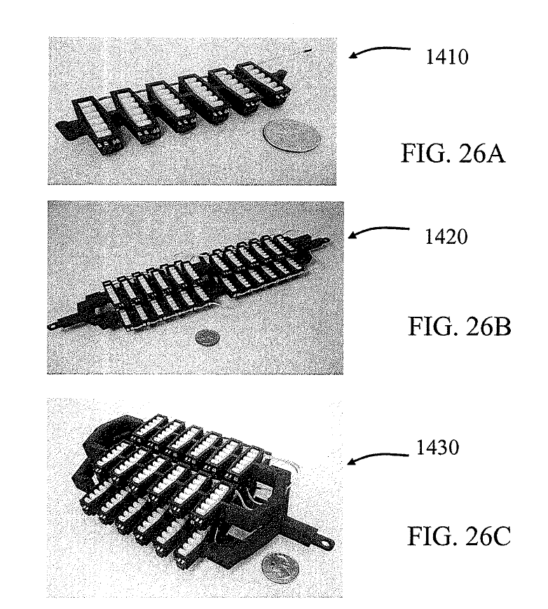

A wide variety of sizes and shapes is configurable using the designed actuator as a building-block. For example, as shown in FIG. 26A, a cellular actuator 1410 can comprise an array of six units connected in series, according to embodiments of the invention, which increases a displacement of the actuator.

The number of stacks and bundles can determined according to a specific application. In one embodiment, as shown in FIG. 26B, a cellular actuator 1420 can comprise twelve stacks or cells and four bundles. The twelve cells are connected in series and four arrays are connected in parallel. These arrays are easily reconfigurable by changing the connectors. In another embodiment, as shown in FIG. 26C, a cellular actuator 1430 can comprise six stacks and seven bundles, which is a configuration for larger force and shorter displacement.

Another salient feature of the proposed actuator is modularity. The basic module of this hierarchical system is a compact PZT stack actuator. The multitude of modular actuator units are connected in series and parallel to build various actuators with diverse stroke, force, and impedance characteristics. This can be done by simply changing the parallel and serial combinations of the same modules.

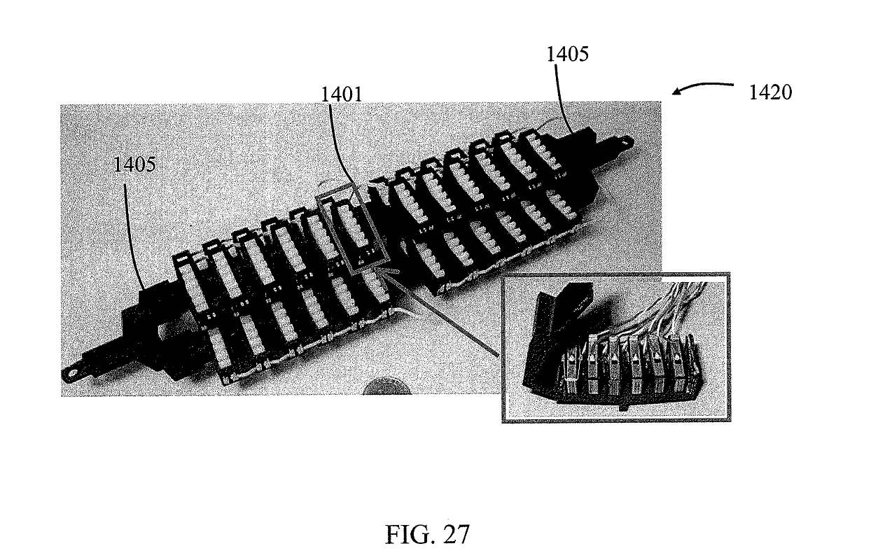

FIG. 27 shows the concept of modular design. The number of stacks and bundles are determined according to a specific application. As shown in FIG. 27, twelve cells are connected in series and four arrays are connected in parallel. In an embodiment, arrays of amplifying units 1401 of an actuator 1420 can be reconfigured by changing connectors 1405. This modular design is based on a powerful method for building diverse actuators with matched load impedance and stroke and force requirements.

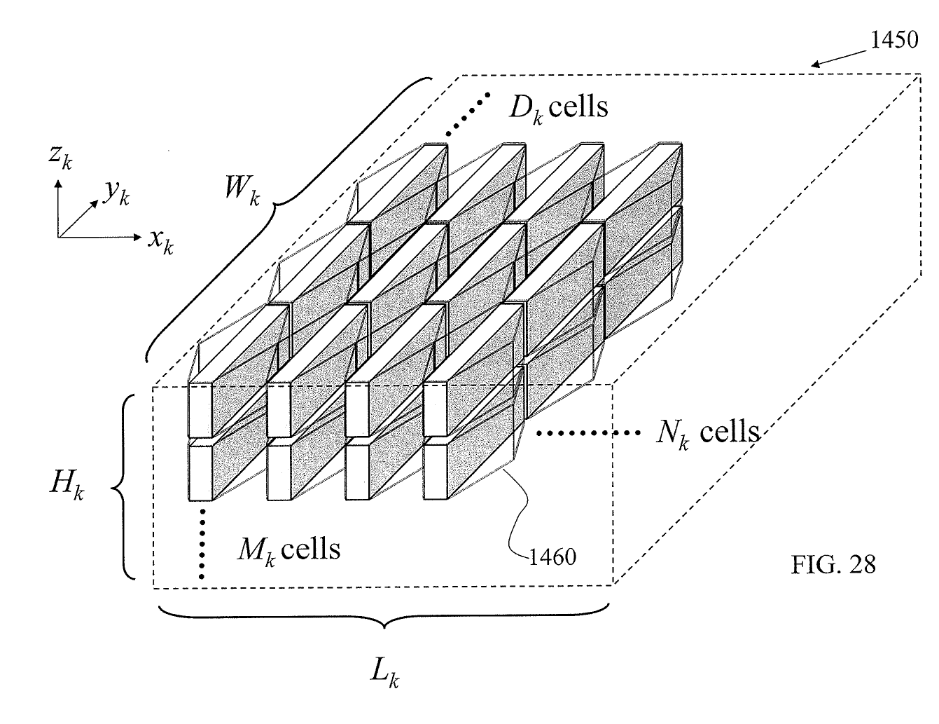

FIG. 28 is a perspective view of a cell stack and bundle, according to embodiments of the invention. As shown in FIG. 28, a layer of a multi-layer strain amplification device 1450 can be configured by connecting a plurality of amplifying layer units 1460 together in serial and parallel. Hereafter, the term “stack” refers to serial connections of the amplifying layer units 1460. Similarly, the term “bundle” refers to parallel connections of the amplifying layer units 1460. In an embodiment, Nₖ, Dₖ, and Mₖ are the number of stacks in the Lₖ direction for the k-th layer, the number of bundles in the direction of Wₖ, and the number of bundles in the direction of Hₖ, respectively.

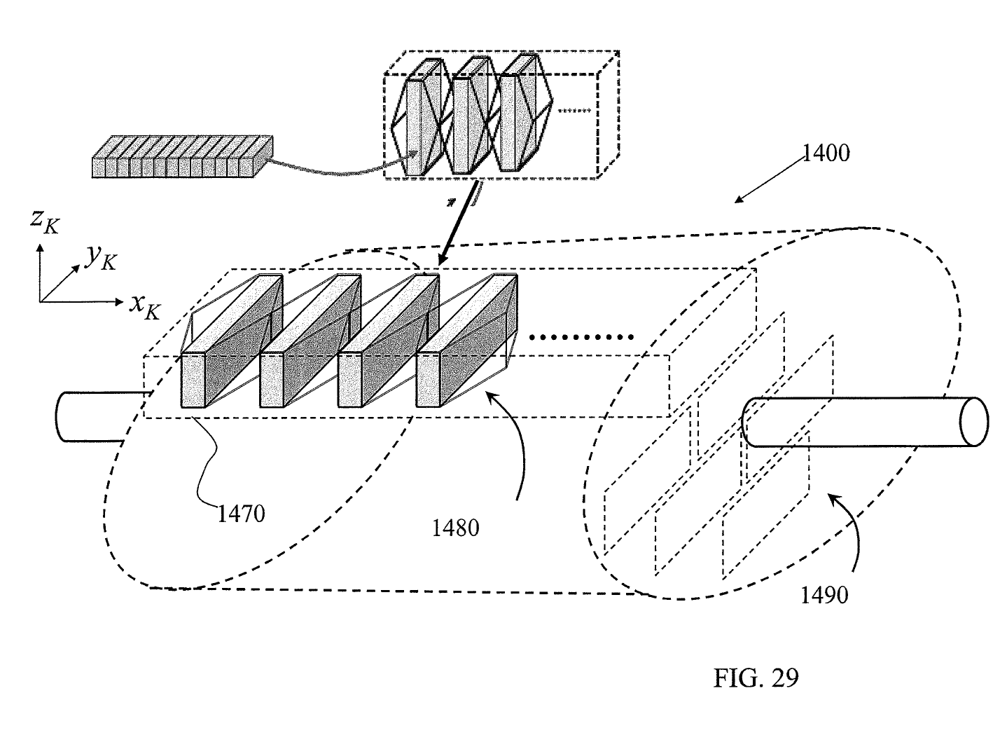

FIG. 29 is a perspective view of a final actuator 1400 incorporating a cell stack 1480 and bundle 1490, according to embodiments of the invention. As shown in FIG. 11, the final actuator 1400 can be configured by connecting a plurality of N_{K} units of at least one final layer 1470 in serial and a plurality of M_{K} units in parallel. Considering the spatial constraint for the final configuration of the actuator 1400, for example, the final layers can be configured relatively freely.

In sum, embodiments of the present invention include a nested rhombus multi-layer mechanism for PZT actuators. The idealized analysis has been given for fundamental design of the nested structure. Through kinematic and static analysis this paper has addressed how the output force and displacement are attenuated by the structural compliances involved in the strain amplification mechanism. A lumped parameter model has been developed to quantify the performance degradation. In an embodiment, nested PZT cellular actuator that weighs only 15 g has produced 21% effective strain 2.49 mm displacement from 12 mm actuator length and a 1.7 N blocking force. A modular design concept has been presented for building reconfigurable cellular actuators with matched stroke and force requirements.

In other embodiments, nonlinear and dynamic modeling such as frequency response can be applied to the devices and methods of the present invention. In other embodiments, analysis of a closed kinematic chain can be formed by serial-parallel mixed configurations described herein. In other embodiments, the devices and methods of the present invention can be applied to practical systems such as robotics.

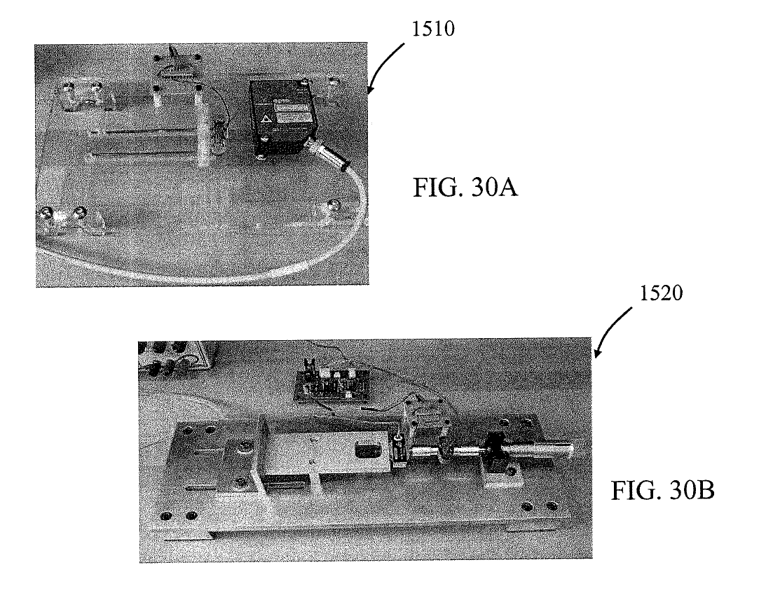

FIGS. 30A and 30B are illustrations of test equipment designed to measure free displacement and blocked force of a multi-layer strain amplification device, according to embodiments of the invention. Specifically, FIG. 30A is an illustration of a blocked force testing stand 1510, and FIG. 30B is an illustration of a free displacement test stand 1520, according to embodiments of the invention.

### Verification of Three-Spring Lumped Parameter Model

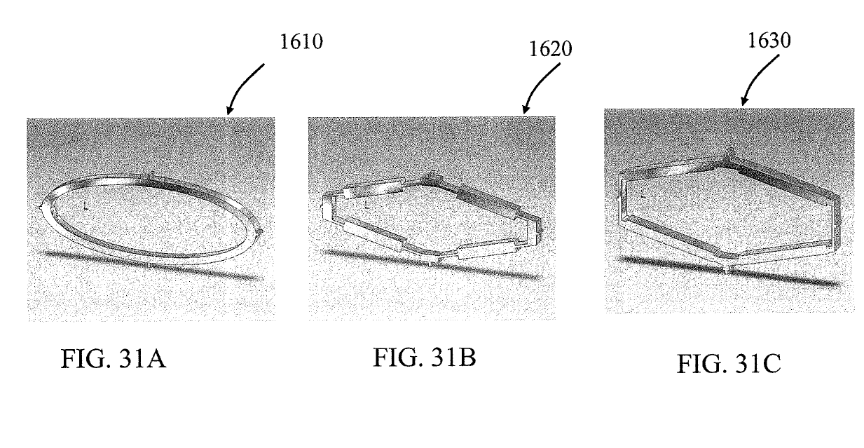

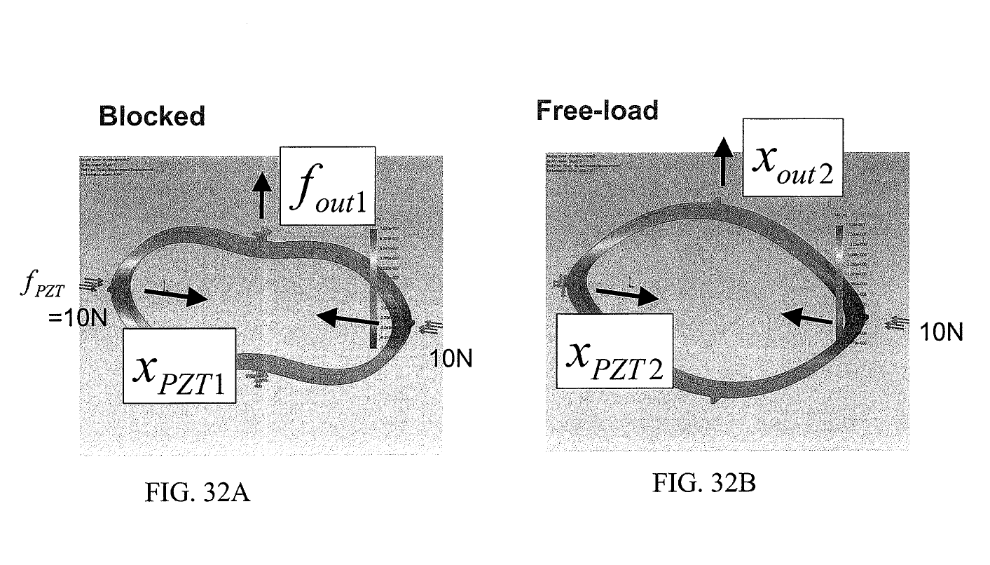

The validity of the proposed lumped parameter model is confirmed by FEM (Finite Element Method). Consider the two amplification mechanisms 1610, 1620 shown in FIGS. 31A and 31B, for example, also referred to as Structure 1 and Structure 2, respectively. The size of each mechanism 1610, 1620 is 40 mm (length, actuation direction)×96 mm (width)×5 mm (thickness). In another embodiment, material such as brass (Young's modulus=100.0 GPa is used. In an embodiment, an amplification mechanism 1630 shown in FIG. 31C can be provided with similar dimensions as those with regard to FIGS. 31A and 31B, also referred to as Structure 3.

The four structural lumped parameters, i.e., α, k_{BI}, k_{BO}, and k_{J}, are calibrated by the displacements and forces from two different conditions; one case is a “blocked case,” for example, shown in FIG. 31A, where the output displacement is totally constrained (or letting k_{load}→∞), and the other one is “free-load case” (or letting k_{load}=0), for example, shown in FIG. 31B. By applying an input force, f_{pzt},Δx_{pzt}^{block} and f₁^{block} are measured for the blocked case, and Δx_{pzt}^{free} and Δx₁^{free} are measured for the free-load case. From equations (30) to (32) we have

$$\begin{matrix}\frac{{f}_{pzt}^{block}}{Δ {x}_{pzt}^{block}} = \frac{{a}^{2} {k}_{BI} {k}_{BO} + {k}_{J} {k}_{BI}}{{a}^{2} {k}_{BO} + {k}_{J} + {k}_{BI}} {=}^{Δ} {X}_{1} & ( 45 ) \\ \frac{{f}_{1}^{block}}{Δ {x}_{pzt}^{block}} = \frac{{ak}_{BI} {k}_{BO}}{{a}^{2} {k}_{BO} + {k}_{J} + {k}_{BI}} {=}^{Δ} {X}_{2} & ( 46 ) \\ \frac{Δ {x}_{1}^{free}}{Δ {x}_{pzt}^{free}} = \frac{{ak}_{BI}}{{k}_{J} + {k}_{BI}} {=}^{Δ} {X}_{3} & ( 47 ) \\ \frac{{f}_{pzt}^{free}}{Δ {x}_{1}^{free}} = \frac{{k}_{J}}{a} {=}^{Δ} {X}_{4} . & ( 48 )\end{matrix}$$

Note that the actual number of independent equations described above is three, which can be confirmed by X₁=X₃(X₂+X₄). This implies that the calibration of the four structural parameters, [α, k_{BI}, k_{BO}, k_{J}], is an ill-posed problem. This can be confirmed by the two-port model representation above with regard to equation (23). The stiffness matrix S is generally given as follows:

$$S = [ \begin{matrix}{X}_{1} & - {X}_{2} \\ - {X}_{2} & \frac{{X}_{3}}{{X}_{2}}\end{matrix} ] \qquad ( 49 )$$

Recall S=S^{T} and it fully represents the relation between the displacements and forces. Therefore, the number of independent elements is three by calibrating S. Unlike the ideal rhombus mechanism consisting of all rigid links, the displacement amplification gain α cannot be defined uniquely as long as the stiffness in the constrained space is finite, i.e., k_{J}>0. Note that the choice of a does not change S or the characteristics of the estimated model; however, a nominal gain \hat{α} should be determined to have a physically feasible lumped parameter model, that is, k_{BI}, k_{BO}, k_{J}>0. One way of determining \hat{α} is based on free-displacement characteristics and kinematic characteristics of the structure such as the angle of the oblique beam θ, i.e., X₃<\hat{α}<cot θ, to satisfy the requirement. X₃ can be assumed as a lower bound of \hat{α} since X₃ is always lower than the actual α if k_{J} is positive. In addition, cot(θ) can be assumed as an upper bound of \hat{α} since this gain is realized only when k_{J}=0.

The following steps estimate the remaining parameters:

$${\hat{k}}_{J} = \hat{a} {X}_{4} , {\hat{k}}_{BI} = \frac{{X}_{3} {\hat{k}}_{J}}{\hat{a} - {X}_{3}} , and {\hat{k}}_{BO} = \frac{( {\hat{k}}_{BI} + {\hat{k}}_{J} ) {X}_{2}}{\hat{a} {\hat{k}}_{BI} - {\hat{a}}^{2} {X}_{2}} .$$

Table 2A shows the observed values from FEM when applying f_{pzt}=10N to the Structures 1-2 shown in FIGS. 31A and 31B, respectively.

TABLE 2A

| | Structure 1 | Structure 2 |
|---|---|---|
| Δx₁^{free} [m] (@f_{pzt} = 10) | 1.95e−05 | 2.61e−04 |
| f₁^{block} [N] (@f_{pzt} = 10) | 2.73 | 2.51 |

Table 2B shows additional observed values from FEM when applying f_{pzt}=10N to the Structures 1-3 shown in FIGS. 31A-31C, respectively.

TABLE 2B

| | Structure 1 | Structure 2 | Structure 3 |
|---|---|---|---|
| ${X}_{1} ( = \frac{{f}_{PZT}^{block}}{{x}_{PZT}^{block}} )$ | 6.64E+06 | 1.25E+07 | 7.67E+05 |
| ${X}_{2} ( = \frac{{f}_{out}^{block}}{{x}_{PZT}^{block}} )$ | 1.81E+06 | 3.14E+06 | 2.87E+05 |
| ${X}_{3} ( = \frac{{x}_{out}^{free}}{{x}_{PZT}^{free}} )$ | 2.876218036 | 3.886319558 | 1.811862187 |
| ${X}_{4} ( = \frac{{f}_{out}^{free}}{{x}_{out}^{free}} )$ | 5.13E+05 | 3.84E+04 | 1.25E+05 |

The structural lumped parameters are calculated as shown in Table 3.

TABLE 3

| | Structure 1 | Structure 2 |
|---|---|---|
| â | 3.2 | 3.9 |
| \hat{k}_{J} [N/m] | 1.64e+06 | 1.50e+05 |
| \hat{k}_{BI} [N/m] | 1.46e+07 | 4.25e+07 |
| \hat{k}_{BO} [N/m] | 1.05e+06 | 1.13e+06 |
| σₘₐₓ [N/m²] | 5.35e+06 | 2.75e+07 |

The nominal amplification gains are determined accordingly based on the observed X₃ and kinematic characteristics to keep all spring constants positive. As shown in Table 2A, the structure 1620 shown in FIG. 31B provides approximately 13 times larger free-load displacement than the structure 1610 shown in FIG. 31A, while the blocking forces of the two structures are almost the same magnitude. This observation suggests that the structure 1620 shown in FIG. 31B has a more favorable structure than the structure 1610 shown in FIG. 31A as an amplification mechanism. This can be explained based on the estimated lumped parameters: The effective stiffness in the constrained space k̅_{B} viewed from the input port is calculated as

$${k}_{B}^{-} {=}^{Δ} \frac{1}{\frac{1}{{k}_{BI}} + \frac{1}{{a}^{2} {k}_{BO}}} \qquad ( 50 )$$

This expression k̅_{B}=6.18e+06 for the structure shown in FIG. 31A and k̅_{B}=1.23e+07 for the structure shown in FIG. 31B. As a result, the structure shown in FIG. 31B has a smaller stiffness in the admissible space, k_{J}, and a larger stiffness in the constrained space, k̅_{B}, compared with that of FIG. 31A. Although the structure shown in FIG. 31B provides relatively good performances, it could also involve a few problems in development due to its complex shape and in strength due to stress concentration at thin sections having large deformation. Maximum stress when producing the free-load displacement is also shown in Table 3.

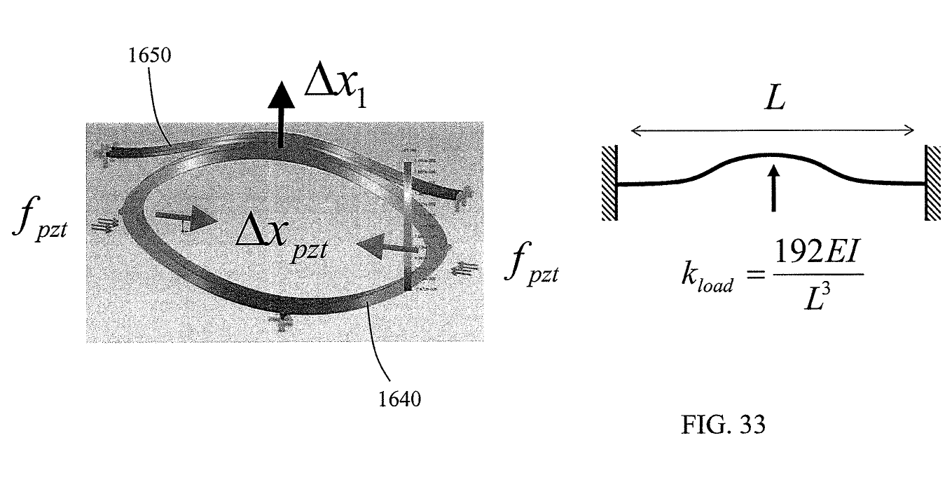

The validity of the calibrated models is confirmed by examining Δx_{pzt} and Δx₁ when connecting the amplification mechanism 1640 to a spring load realized by a fixed beam 1650 shown in FIG. 33. The length of the beam 1650 is L=100 mm. In an embodiment, brass is used as a material. Three different thicknesses, from 1 mm, 2 mm, to 3 mm, are used to vary the stiffness. Table 4A shows the comparison of the estimated displacements of Structures 1 and 2 shown in FIGS. 31A and 31B from the proposed lumped parameter model and the true values from FEM analysis. As can be observed in the Table 4A, the estimated values agree well with the true values, confirming the validity of the model. Table 4B shows estimated displacements of Structure 3 shown in FIG. 31C from the proposed lumped parameter model and the true values from FEM analysis.

TABLE 4A

| | | Structure 1 | | | Structure 2 | | |
|---|---|---|---|---|---|---|---|
| Thickness | Disp. [μm] | FEM | Estimated | Error [%] | FEM | Estimated | Error [%] |
| 1 [mm] | Δxpzt | 6.48 | 6.49 | 0.035 | 36.76 | 37.20 | 1.184 |
| | Δx₁ | 18.40 | 18.42 | 0.172 | 141.5 | 143.1 | 1.163 |
| 2 [mm] | Δxpzt | 5.10 | 5.11 | 0.187 | 9.47 | 9.57 | 1.098 |
| | Δx₁ | 13.28 | 13.34 | 0.467 | 34.09 | 34.46 | 1.098 |
| 3 [mm] | Δxpzt | 3.56 | 3.56 | 0.051 | 3.65 | 3.67 | 0.492 |
| | Δx₁ | 7.61 | 7.63 | 0.301 | 11.23 | 11.30 | 0.267 |

| | | |
|---|---|---|
| Average [%] | 0.202 | 0.884 |

TABLE 4B
Structure 3

| Thickness | Disp. [um] | FEM | estimated | error(%) |
|---|---|---|---|---|
| 1 [mm] | Δxpzt | 39.83 | 39.90 | 0.104 |
| | Δx₁ | 68.61 | 68.80 | 0.247 |
| 2 [mm] | Δxpzt | 26.44 | 26.63 | 0.736 |
| | Δx₁ | 34.35 | 34.38 | 0.085 |
| 3 [mm] | Δxpzt | 18.76 | 19.01 | 1.351 |
| | Δx₁ | 14.71 | 14.58 | 0.867 |
| Average [%] | | | | 0.565 |

In another embodiment, the parameter estimation based on the lumped parameter model can be provided based on the following:

$$\begin{matrix}\frac{{f}_{PZT 1}}{{x}_{PZT 1}} = \frac{{a}^{2} {k}_{1} {k}_{2} + {k}_{3} {k}_{1}}{{a}^{2} {k}_{2} + {k}_{3} + {k}_{1}} = {X}_{1} & ( 51 ) \\ \frac{{f}_{out 1}}{{x}_{PZT 1}} = \frac{{a}^{2} {k}_{1} {k}_{2}}{{a}^{2} {k}_{2} + {k}_{3} + {k}_{1}} = {X}_{2} & ( 52 ) \\ \frac{{x}_{out 2}}{{x}_{PZT 2}} = \frac{{ak}_{1}}{{k}_{1} + {k}_{3}} = {X}_{3} & ( 53 ) \\ \frac{{f}_{PZT 2}}{{x}_{out 2}} = \frac{{k}_{3}}{a} = {X}_{4} & ( 54 )\end{matrix}$$

wherein α, k₁, k₂, k₃ are four structural lumped parameters.
However, in this embodiment, X₁=X₃(X₄+X₂).

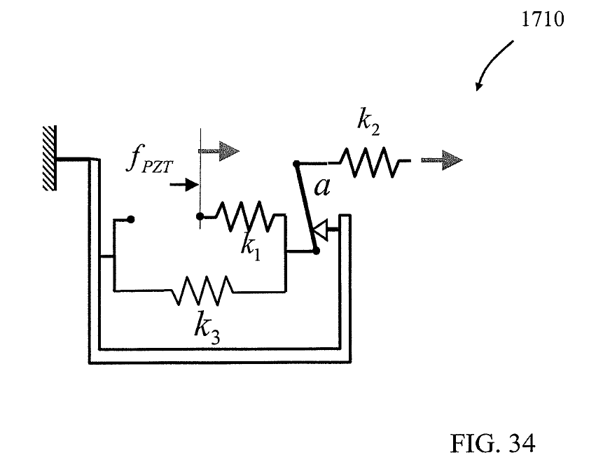

Accordingly, in accordance with other embodiments, parameter estimation of a three-spring model as shown in FIG. 34 is performed by setting α, wherein a good approximation is given by equations (55)-(58)

$$\begin{matrix}{X}_{3} = \frac{{ak}_{1}}{{k}_{1} + {k}_{3}} & ( 55 ) \\ {k}_{3} = {aX}_{4} & ( 56 ) \\ {k}_{1} = \frac{{k}_{3} {X}_{4}}{a - {X}_{3}} & ( 57 ) \\ {k}_{2} = \frac{( {k}_{1} + {k}_{3} ) {X}_{2}}{{ak}_{1} - {a}^{2} {X}_{2}} & ( 58 )\end{matrix}$$

### Necessity of Three Lumped Springs

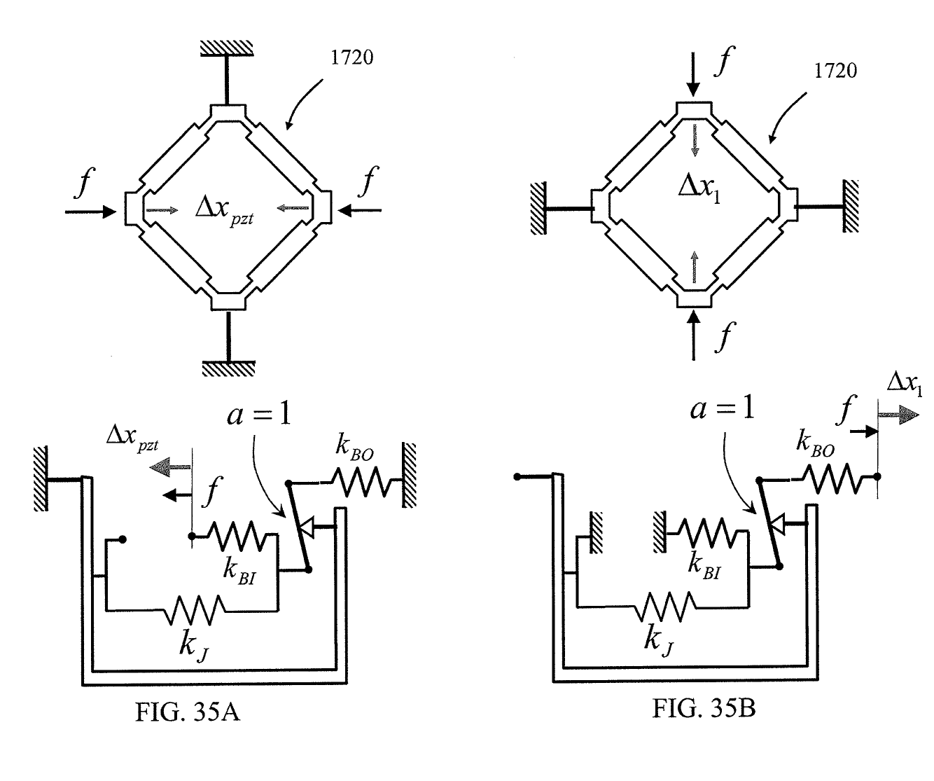

Consider two constrained cases shown in FIGS. 35A and 35B to confirm the necessity of three lumped springs. For simplicity, the amplification mechanism is designed to have a square shape resulting in α=1. Δx₁=Δx_{pzt} must hold for the displacements when applying the same magnitude of force f, which is a basic requirement of Castigliano's theorems. By using the proposed lumped parameter model, these constrained cases are represented by the illustrative figures herein. The condition Δx₁=Δx_{pzt} is satisfied if k_{BI}=k_{BO}. This can also be confirmed in equation (49) where the off-diagonal elements are the same. As described herein, this lumped parameter model has a redundancy in parameter calibration; however, three spring elements are minimally required to satisfy this condition.

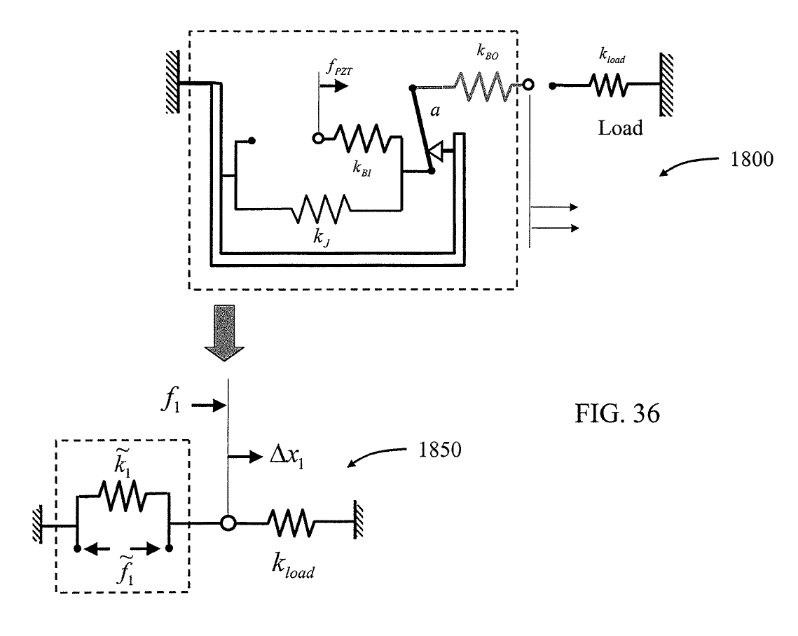

In another embodiment, a lumped parameter model 1800 and simplified equivalent model 1850 shown in FIG. 36 are described as follows based on parameters described herein:

$$\begin{matrix}{\tilde{k}}_{1} = \frac{{k}_{BO} ( {k}_{BI} {k}_{J} + {k}_{PZT} {k}_{J} + {k}_{BI} {k}_{PZT} )}{( {a}^{2} {k}_{BI} {k}_{BO} + {k}_{BI} {k}_{J} ) + {k}_{PZT} ( {a}^{2} {k}_{BO} + {k}_{J} + {k}_{BI} )} & ( 59 ) \\ {\tilde{f}}_{1} = \frac{{ak}_{BI} {k}_{BO}}{( {a}^{2} {k}_{BI} {k}_{BO} + {k}_{BI} {k}_{J} ) + {k}_{PZT} ( {a}^{2} {k}_{BO} + {k}_{J} + {k}_{BI} )} {f}_{pzt} & ( 60 )\end{matrix}$$

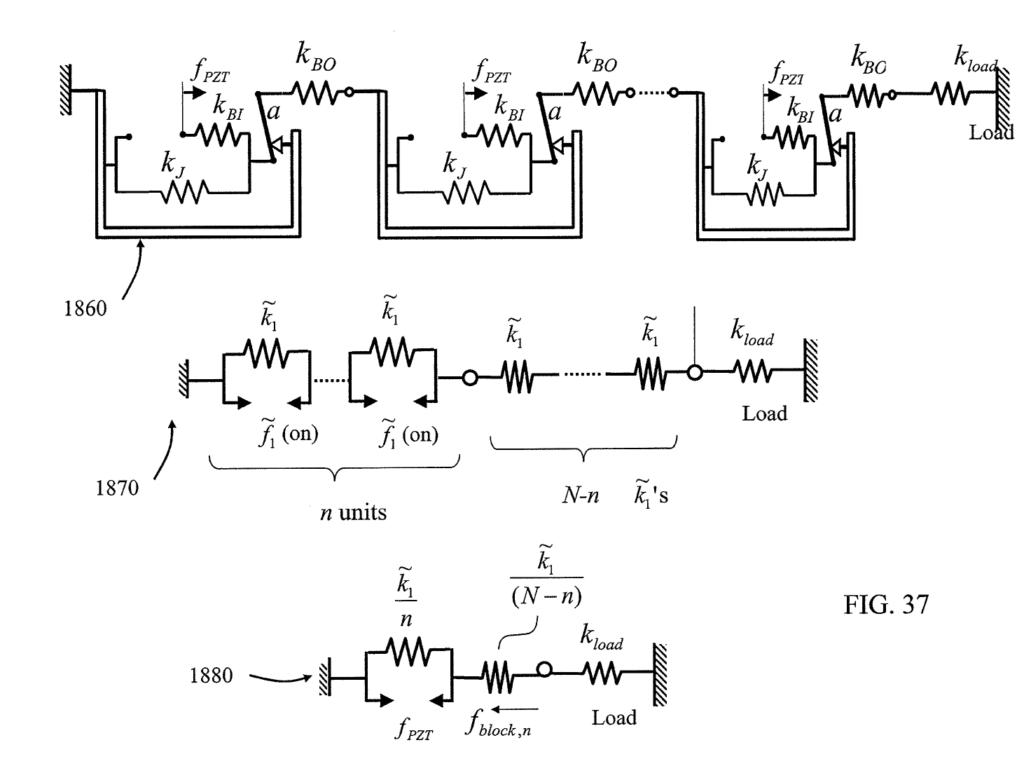

In another embodiment, as shown in FIG. 37, a lumped parameter model 1860 and simplified equivalent model 1880 can include a plurality of units 1870 coupled to each other. The simplified equivalent model being determined in part by:

$${f}_{block , n} = \frac{n}{N} {f}_{I}^{block} \qquad ( 61 )$$

### Parameter Calibration of Second Layer Rhombus Mechanism

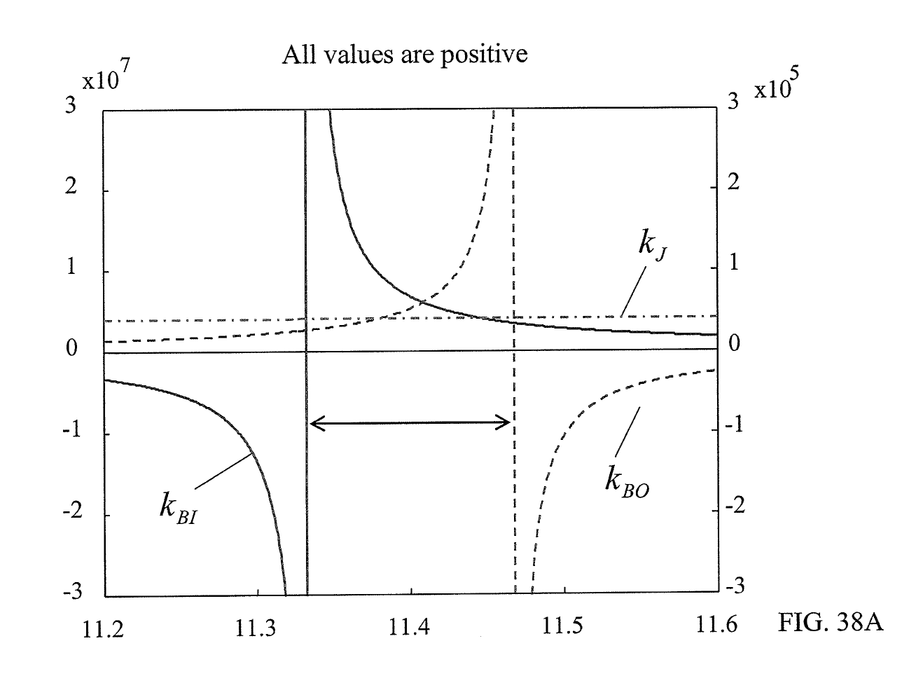

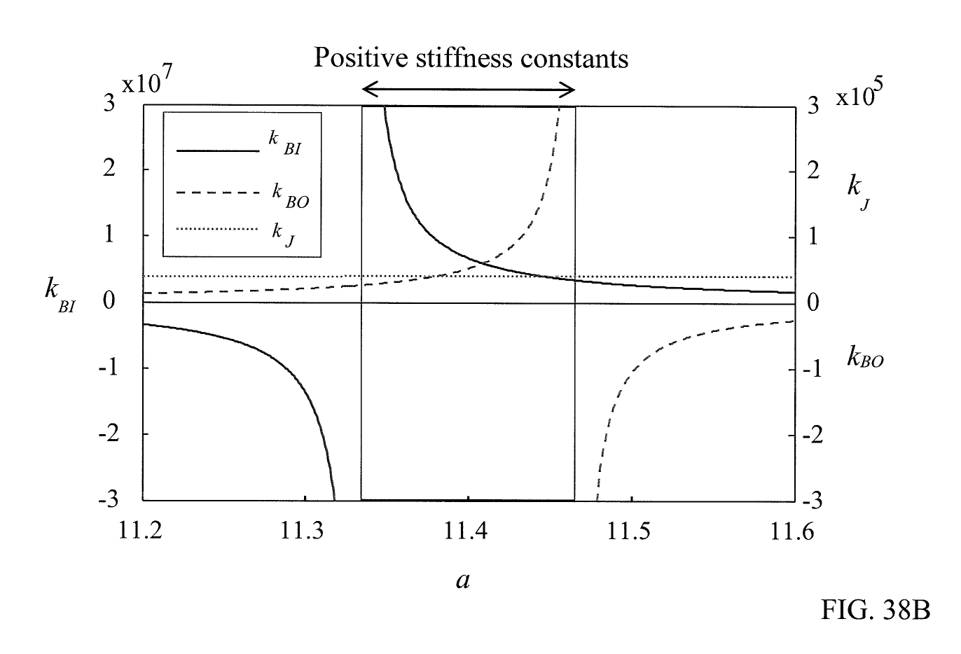

X₁=3.39×10⁶, X₂=2.95×10⁵, X₃=11.33, and X₄=3.50×10³ are obtained from FEM analysis. The range of α₂ that makes all spring constants positive is shown in FIGS. 38A and 38B. Finally \hat{α}₂=11.4 is chosen, which is between X₃ and cot θ (=11.5).

While this invention has been particularly shown and described with references to preferred embodiments thereof, it will be understood to those skilled in the art that various changes in form and details may be made herein without departing from the spirit and scope of the invention as defined in the appended claims.

What is claimed is:

1. A multi-layer strain amplification device, comprising:
at least one first amplifying layer unit comprising a plurality of actuators; and
a second amplifying layer unit positioned about the at least one first amplifying layer unit, wherein a strain of the at least one first amplifying layer unit is amplified by the second amplifying layer unit.

2. The device of claim 1, wherein the at least one first amplifying layer unit and the second amplifying layer unit are configured as a nested rhombus structure.

3. The device of claim 1, wherein the actuators are at least one of in series with and in parallel with each other.

4. The device of claim 3, wherein an output axis of the serially-connected actuators is perpendicular to an output axis of the second amplifying layer unit.

5. The device of claim 1, wherein the actuators are piezoelectric actuators.

6. The device of claim 1, wherein the at least one first amplifying unit is positioned in a first layer of the device, the at least one second amplifying unit strain is positioned in a second layer of the device, wherein an amplification gain of the device increases exponentially as a number of layers of the device increases.

7. The device of claim 1, wherein displacements of each first actuator are aggregated and transmitted through the at least one first amplifying layer unit and the second amplifying layer unit, resulting in an output displacement at the second amplifying layer unit.

8. The device of claim 1, wherein a displacement of the device is amplified when the at least one first amplifying unit expands in a first direction and contracts in a second direction.

9. The device of claim 8, wherein the first direction is perpendicular to the second direction.

10. The device of claim 1, wherein the at least one first amplifying layer unit further comprises a rhombus structure positioned about each actuator, the rhombus structure including a rigid beam and a flexible joint.

11. The device of claim 1, wherein a plurality of first amplifying layer units are connected in series to increase an output displacement.

12. The device of claim 1, wherein a plurality of first amplifying layer units are connected in parallel to increase an output force.

13. A method of forming a multi-layer strain amplification device, comprising:
providing at least one first amplifying layer unit including a plurality of actuators; and
positioning a second amplifying layer unit about the at least one first amplifying layer unit to amplify a strain of the at least one first amplifying layer unit.

14. The method of claim 13 further comprising configuring the at least one first amplifying layer unit and the second amplifying layer unit as a nested rhombus structure.

15. The method of claim 13 further comprising positioning the actuators to be at least one of in series with and in parallel with each other.

16. The method of claim 13, wherein the at least one first amplifying unit is positioned in a first layer of the device, the at least one second amplifying unit strain is positioned in a second layer of the device, wherein an amplification gain of the device increases exponentially as a number of layers of the device increases.

17. The method of claim 13, wherein a displacement of the device is amplified when the at least one first amplifying unit expands in a first direction and contracts in a second direction.

18. The method of claim 13, wherein providing at least one first amplifying layer unit comprises positioning a rhombus structure about each actuator, the rhombus structure including a rigid beam and a flexible joint.

19. A method of amplifying strain of an actuator, comprising:
providing at least one first amplifying layer unit having a first strain;
amplifying the first strain;
positioning a second amplifying layer unit about the at least one first amplifying layer unit; and
amplifying the amplified first strain.
